(19) United States
(12) Patent Application Publication
(10) Pub. No.: US 2025/0256407 A1
(43) Pub. Date: Aug. 14, 2025

(54) SUBSTRATE PROCESSTNG APPARATUS AND SUBSTRATE PROCESSING METHOD

(71) Applicant: SCREEN Holdings Co., Ltd., Kyoto (JP)

(72) Inventor: Ichiro MITSUYOSHI, Kyoto (JP)

(21) Appl. No.: 19/047,101

(22) Filed: Feb. 6, 2025

(30) Foreign Application Priority Data
Feb. 8, 2024 (JP) 2024-018105

(51) Int. Cl. B25J 15/00; B08B 3/04; B25J 9/16

(52) U.S. Cl. CPC B25J 15/0014; B25J 9/1664; B08B 3/04

(57) ABSTRACT

A substrate processing apparatus includes a pitch converting unit that converts a pitch of a plurality of substrates between an unequal pitch at which a first interval and a second interval wider than the first interval are alternately repeated and a narrow pitch at which the first interval is repeated. The pitch converting unit includes: the plurality of holding members that hold the plurality of substrates aligned at the unequal pitch; and the moving unit configured to move the plurality of holding members in the alignment direction of the plurality of substrates so as to switch the plurality of substrates between an unequal pitch arrangement in which the plurality of substrates are aligned at the unequal pitch, and a narrow pitch arrangement in which the plurality of substrates are aligned at the narrow pitch. Each of the plurality of holding members has two holding grooves for holding two substrates, respectively. The two holding grooves are spaced apart by a first interval.

### CROSS-REFERENCE TO RELATED APPLICATIONS

This application claims priority to Japanese Patent Application No. 2024-018105 filed Feb. 8, 2024, the subject matter of which is incorporated herein by reference in entirety.

### BACKGROUND

### Technical Field

The present invention relates to a substrate processing apparatus and a substrate processing method for processing a substrate. Examples of such a substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

Conventionally, a substrate processing apparatus that immerses and processes a batch of a plurality of substrates in a processing liquid has been known. Such a substrate processing apparatus includes an orientation converting mechanism (orientation converting unit) and a pusher (pusher mechanism) (see, for example, Japanese Patent Application Laid-Open No. 2010-093230). The orientation converting mechanism converts the orientation of the substrate to and from a horizontal orientation from and to a vertical orientation. The pusher can pass and receive a plurality of substrates in the vertical orientation to and from the orientation converting mechanism by causing a lifting holder (pusher member) to move up and down.

After the lifting holder receives twenty-five substrates from the orientation converting mechanism, the lifting holder is turned by 180 degrees about the vertical axis. By turning the lifting holder by 180 degrees, the twenty-five substrates held by the lifting holder is shifted by a half pitch. In this configuration, another twenty-five substrates are passed from the orientation converting mechanism to the lifting holder. As a result, the twenty-five substrates passed later in time are inserted between the twenty-five substrates passed earlier in time, and a substrate group including fifty substrates in total is formed on the lifting holder. At this time, two adjacent substrates are positioned face to face, in which the front surfaces (or the rear surfaces) thereof face each other. The fifty substrates held by the lifting holder are also aligned at a half pitch that is a half of a substrate holding pitch used inside a carrier.

Japanese Patent Application Laid-Open No. 2022-077177 discloses a pitch converting unit. The pitch converting unit includes a base member, twenty-five chucks (holding members) that are slidably provided to the base member, and a pitch changing mechanism that changes the interval between the chucks. Each of the chucks suctions a part of the peripheral edge of one substrate, with the vacuum.

### SUMMARY

In order to reduce the amount of processing liquid (chemical liquid and cleaning liquid) used in the substrate processing apparatus, there is a demand for aligning a plurality of substrates at a pitch narrower than the half pitch, and processing the plurality of substrates aligned at the narrower pitch, as a batch. In such a case, for example, if the pitch converting unit is to use fifty holding members to hold fifty substrates, each of the holding members needs to be reduced in width in the alignment direction of the fifty substrates. Therefore, it becomes difficult to ensure the dimensional accuracy of the holding members, and for the holding members to hold the respective substrates in the vertical orientation.

The present invention has been made in view of such circumstances, and an object of the present invention is to provide a substrate processing apparatus and a substrate processing method including a pitch converting unit capable of holding each substrate in the vertical orientation, easily.

In order to achieve such an object, the present invention uses the following configurations. That is, a substrate processing apparatus according to the present invention is a substrate processing apparatus for processing a plurality of substrates, the substrate processing apparatus including: a pitch converting unit that converts a pitch between the plurality of substrates, between an unequal pitch in which a first interval and a second interval wider than the first interval are repeated alternately, and a narrow pitch in which the first interval is repeated; a substrate processing unit that processes the plurality of substrates aligned at the narrow pitch, as a batch; and a main transporting mechanism that transports the plurality of substrates aligned at the narrow pitch to the substrate processing unit, in which the pitch converting unit includes: a plurality of holding members that hold the plurality of substrates aligned at the unequal pitch; a moving unit configured to move the plurality of holding members in an alignment direction of the plurality of substrates so as to switch the plurality of substrates between an unequal pitch arrangement in which the plurality of substrate are arranged at the unequal pitch, and a narrow pitch arrangement in which the plurality of substrates are aligned at the narrow pitch; and each of the plurality of holding members has two holding grooves that hold two substrates, respectively, among the plurality of substrates, and the two holding grooves are spaced apart from each other by the first interval.

In the substrate processing apparatus according to the present invention, the pitch converting unit includes: the plurality of holding members that hold the plurality of substrates aligned at the unequal pitch; and the moving unit configured to move the plurality of holding members in the alignment direction of the plurality of substrates so as to switch the plurality of substrates between the unequal pitch arrangement in which the plurality of substrates are aligned at the unequal pitch, and the narrow pitch arrangement in which the plurality of substrates are aligned at the narrow pitch. Each of the plurality of holding members has the two holding grooves that hold two substrates, respectively, among the plurality of substrates. The two holding grooves are spaced apart from each other by the first interval (first interval<second interval). Because each of the holding members has the two holding grooves for holding two substrates, each of the holding members can be provided with a relatively large width, in the alignment direction of the plurality of substrates. With this, it is possible to ensure the dimensional accuracy of the holding members, and to allow the plurality of holding members to hold the substrates in the vertical orientation, easily.

Furthermore, in the substrate processing apparatus described above, preferably, the two holding grooves are spaced apart from each other by the first interval that is smaller than a half of the second interval. In the unequal pitch, the first interval and the second interval wider than the first interval are repeated alternately. Let us assume herein that there is a predetermined interval constituting of one first interval and one second interval. Assuming that the predetermined interval is 10 mm, for example, by setting the first interval smaller than a half of the second interval, it is possible to set the first interval smaller than ⅓ times 10 mm, and to set the length of the first interval to any length, e.g., 3 mm, without any fractional part below the decimal point.

Furthermore, in the substrate processing apparatus described above, preferably, the two holding grooves are spaced apart from each other by the first interval that is a half of the second interval. In the unequal pitch, the first interval and the second interval wider than the first interval are arranged alternately. Let us assume herein that there is a predetermined interval constituting of one first interval and one second interval. Assuming that the predetermined interval is 10 mm, for example, by setting the first interval equal to a half of the second interval, it is possible to set the first interval to a value smaller than ⅓ times 10 mm, and to set the second interval to a value ⅔ times 10 mm.

In the substrate processing apparatus described above, preferably, the moving unit includes a guide rail that supports the plurality of holding members in a manner movable in the alignment direction; an extending/retracting mechanism that extends and retracts the plurality of holding members in the alignment direction; and a driving unit that drives the extending/retracting mechanism. The guide rail can support the plurality of holding members in a manner movable in the alignment direction. The extending/retracting mechanism driven by the driving unit can extend/retract the plurality of holding members.

In the substrate processing apparatus described above, the extending/retracting mechanism preferably includes: a housing that is provided to a first holding member, among the plurality of holding members; a protrusion that protrudes from a second holding member toward the first holding member positioned adjacently to the second holding member, among the plurality of holding members, and becomes housed in the housing when the plurality of holding members are retracted in the alignment direction; and a stopper that is provided to a tip of the protrusion, that prevents the protrusion from coming out of the housing when the plurality of holding members are extended in the alignment direction. The extending/retracting mechanism can extend/retract the plurality of holding members using the housing, the protrusion, and the stopper.

In the substrate processing apparatus described above, preferably, the extending/retracting mechanism further includes an elastic member provided between the first holding member and the second holding member. While the plurality of holding members are in between of being extended in the alignment direction and retracted in the alignment direction, the holding members are free to move from their positions. By providing the elastic member, it is possible to suppress movements of the holding members that are free to move. In this manner, it is possible to suppress shaking of the plurality of substrates held in the plurality of holding grooves in the vertical orientation. Thus, for example, it is possible to suppress a contact of two adjacently positioned substrates.

Furthermore, the substrate processing apparatus described above preferably further includes: an orientation converting mechanism that converts the plurality of substrates to and from a horizontal orientation from and to a vertical orientation; a pusher mechanism that includes a pusher member that holds the plurality of substrates aligned at the unequal pitch in the vertical orientation, and is capable of passing the plurality of substrates to and from the orientation converting mechanism; and a delivering mechanism that transports the plurality of substrates aligned at the unequal pitch, to and from the pusher member from and to the pitch converting unit.

Furthermore, preferably, the substrate processing apparatus described above further includes a control unit, in which the control unit is configured to: cause the orientation converting mechanism to convert two or more first substrates held at a reference pitch in which a reference interval that is a sum of the first interval and the second interval is repeated, from the horizontal orientation to the vertical orientation, as a batch; cause the pusher member to receive the two or more first substrates having been converted to the vertical orientation, and to hold the two or more first substrates aligned at the reference pitch in the vertical orientation; cause the pusher mechanism to move the two or more first substrates held by the pusher member by the first interval in an alignment direction of the two or more first substrates; cause the orientation converting mechanism to convert two or more second substrates held at the reference pitch, from the horizontal orientation to the vertical orientation, as a batch; cause the pusher member to receive the two or more second substrates having been converted to the vertical orientation; cause the pusher member to hold the plurality of substrates including the two or more first substrates and the two or more second substrates, the first substrates and the second substrates being arranged alternately and aligned at the unequal pitch; cause the delivering mechanism to transport the plurality of substrates aligned at the unequal pitch from the pusher member to the pitch converting unit; cause the pitch converting unit to convert a pitch of the plurality of substrates from the unequal pitch to the narrow pitch; cause the main transporting mechanism to transport the plurality of substrates aligned at the narrow pitch to the substrate processing unit; and cause the substrate processing unit to process the plurality of substrates aligned at the narrow pitch as a batch.

The two or more first substrates are aligned at the reference pitch, and the two or more second substrates are aligned at the reference pitch. The two or more second substrates are arranged in a manner offset from to the two or more respective first substrates by the first interval in the alignment direction. As a result, a plurality of substrates including the two or more first substrates and the two or more second substrates that are alternately arranged become aligned at the unequal pitch. The pitch converting unit then converts the pitch between the plurality of substrates that are aligned at the unequal pitch, to the narrow pitch. That is, a first pitch conversion is performed by aligning the two or more first substrates and the two or more second substrates at the unequal pitch, and a second pitch conversion is performed by converting the unequal pitch to the narrow pitch. By performing the pitch conversion in two stages, it becomes possible to convert the pitch of the two or more first substrates and the two or more second substrates that are aligned at the reference pitch, easily, to the narrow pitch.

In addition, preferably, the substrate processing apparatus described above further includes a carrier shelf for placing a carrier housing N substrates that are aligned at a reference pitch in which a reference interval that is a sum of the first interval and the second interval is repeated, where N is a natural number equal to or more than two, and the orientation converting mechanism includes an orientation converting unit that converts the two or more first substrates and the two or more second substrates from or to the horizontal orientation to or from the vertical orientation, and a substrate handling mechanism that transports the N substrates from and to the carrier placed on the carrier shelf, to and from the orientation converting unit.

Furthermore, preferably, the substrate processing apparatus described above further includes a control unit, in which the control unit is configured to: cause the substrate handling mechanism to transport N substrates aligned at the reference pitch in the horizontal orientation on a first carrier placed on the carrier shelf, from the first carrier to the orientation converting unit; cause the substrate handling mechanism to transport P substrates aligned at the reference pitch in the horizontal orientation, the P substrates being substrates among N substrates on a second carrier placed on the carrier shelf, from the second carrier to the orientation converting unit; cause the orientation converting unit to convert the two or more first substrates including the N substrates from the first carrier and the P substrates held at the reference pitch, from the horizontal orientation to the vertical orientation, as a batch; cause the pusher member to receive the two or more first substrates having been converted to the vertical orientation, and to hold the two or more first substrates aligned at the reference pitch; cause the pusher mechanism to move the two or more first substrates held by the pusher member by the first interval in an alignment direction of the two or more first substrates; cause the substrate handling mechanism to transport Q substrates aligned at the reference pitch in the horizontal orientation to the orientation converting unit, the Q substrates being remainder of the N substrates on the second carrier; cause the substrate handling mechanism to transport N substrates in the horizontal orientation aligned at the reference pitch on a third carrier placed on the carrier shelf, from the third carrier to the orientation converting unit; cause the orientation converting unit to convert the two or more second substrates including the Q substrates and the N substrates from the third carrier and held at the reference pitch, from the horizontal orientation to the vertical orientation, as a batch; cause the pusher member to receive the two or more second substrates having been converted to the vertical orientation; cause the pusher member to hold the plurality of substrates including the two or more first substrates and the two or more second substrates that are arranged alternately at the unequal pitch; cause the delivering mechanism to transfer the plurality of substrates that are aligned at the unequal pitch, from the pusher member to the pitch converting unit; cause the pitch converting unit to convert the pitch of the plurality of substrates from the unequal pitch to the narrow pitch; cause the main transporting mechanism to transport the plurality of substrates aligned at the narrow pitch to the substrate processing unit; and cause the substrate processing unit to process the plurality of substrates aligned at the narrow pitch, as a batch.

The first pitch conversion is performed by aligning N substrates housed in each of the three carriers at the reference pitch, to the unequal pitch, and the second pitch conversion is performed by converting the unequal pitch to the narrow pitch. By performing the pitch conversion in two stages, it is possible to convert the pitch of the N substrates that are aligned at the reference pitch inside each of the three carriers, easily, to the narrow pitch.

Furthermore, preferably, the substrate processing apparatus described above further includes a control unit, in which the control unit is configured to: cause the main transporting mechanism to transport the plurality of substrates aligned at the narrow pitch in the vertical orientation, the plurality of substrates having been processed as a batch by the substrate processing unit, to a position above the pitch converting unit; cause the pitch converting unit to hold the plurality of substrates aligned at the narrow pitch in the vertical orientation; cause the pitch converting unit to convert the pitch of the plurality of substrates from the narrow pitch to the unequal pitch; cause the delivering mechanism to transport the plurality of substrates aligned at the unequal pitch from the pitch converting unit to the pusher member; cause the pusher member to hold the plurality of substrates in the vertical orientation, the plurality of substrates being a plurality of substrates that are aligned at the unequal pitch, and in which the two or more first substrates and the two or more second substrates are arranged alternately; cause the orientation converting mechanism to receive the two or more first substrates aligned at the reference pitch, among the plurality of substrates, from the pusher member, and to convert the two or more first substrates from the vertical orientation to the horizontal orientation; and cause the orientation converting mechanism to receive the two or more second substrates aligned at the reference pitch, among the plurality of substrates, from the pusher member, and to convert the two or more second substrates from the vertical orientation to the horizontal orientation, in which in the reference pitch, a reference interval equal to a sum of the first interval and the second interval is repeated.

The first pitch conversion is performed by aligning the plurality of narrow pitch substrates having been processed as a batch by the substrate processing unit, at the unequal pitch. The plurality of substrates that are aligned at the unequal pitch and in which the two or more first substrates and the two or more second substrates are arranged alternately are decomposed into the two or more first substrates and the two or more second substrates that are arranged at the reference pitch. The second pitch conversion is thus performed. By performing the pitch conversion in two stages, the pitch of the plurality of substrates (the two or more first substrates and the two or more second substrates) aligned at the narrow pitch can be easily converted to the reference pitch.

A substrate processing method according to the present invention is a substrate processing method for processing a plurality of substrates, the substrate processing method including: a pitch converting step of causing a pitch converting unit to convert a pitch between the plurality of substrates from an unequal pitch in which a first interval and a second interval wider than the first interval are repeated alternately, to a narrow pitch in which the first interval is repeated; a substrate transporting step of causing a main transporting mechanism to transport the plurality of substrates aligned at the narrow pitch to a substrate processing unit; and a substrate processing step of causing the substrate processing unit to process the plurality of substrates aligned at the narrow pitch, as a batch, in which the pitch converting step includes: a holding step of causing a plurality of holding members to hold the plurality of substrates aligned at the unequal pitch, while holding two substrates, among the plurality of substrates, at the first interval with two holding grooves that are provided to each of the plurality of holding members and spaced apart from each other by the first interval; a pitch conversion executing step of causing a moving unit to move the plurality of holding members in an alignment direction of the plurality of substrates so as to switch the plurality of substrates from an unequal pitch arrangement in which the plurality of substrates are aligned at the unequal pitch to a narrow pitch arrangement in which the plurality of substrates are aligned at the narrow pitch.

With the substrate processing apparatus and the substrate processing method according to the present invention, the pitch converting unit can easily hold each substrate in the vertical orientation.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view illustrating a schematic configuration of a substrate processing apparatus according to a first embodiment;

FIG. 2 is a plan view illustrating a configuration of a transfer block and elements therearound;

FIG. 3 is a side view illustrating a substrate handling mechanism;

FIG. 4 is a side view illustrating an orientation converting unit;

FIG. 5 is a side view illustrating a pusher mechanism;

FIG. 6 is a side view illustrating a longitudinal cross section of a pusher member;

FIG. 7 is a side view illustrating elements such as a delivering mechanism and two pitch converting units, in a view as indicated by arrows A-A in FIG. 2;

FIG. 8 is a plan view mainly illustrating an incoming delivering mechanism and an outgoing delivering mechanism;

FIG. 9 is a plan view mainly illustrating an intermediating mechanism;

FIG. 10 is a side view illustrating a schematic configuration of a pitch converting unit that holds a plurality of substrates aligned at an unequal pitch;

FIG. 11 is a side view illustrating a schematic configuration of the pitch converting unit holding a plurality of substrates that are aligned at a narrow pitch;

FIG. 12 is a bottom view mainly illustrating an extending/retracting mechanism included in the pitch converting unit holding a plurality of substrates that are aligned at the unequal pitch;

FIG. 13 is a bottom view mainly illustrating an extending/retracting mechanism included in the pitch converting unit holding a plurality of substrates that are aligned at the narrow pitch;

FIG. 14 is a flowchart for explaining a former half of an operation of the substrate processing apparatus;

FIGS. 15A to 15C are side views for explaining the operation of the substrate processing apparatus;

FIGS. 16A to 16C are side views for explaining the operation of the substrate processing apparatus;

FIGS. 17A to 17C are side views for explaining the operation of the substrate processing apparatus;

FIGS. 18A and 18B are side views for explaining the operation of the substrate processing apparatus;

FIGS. 19A and 19B are side views for explaining the operation of the substrate processing apparatus;

FIGS. 20A and 20B are side views for explaining the operation of the substrate processing apparatus;

FIG. 21 is a flowchart for explaining a latter half of an operation of the substrate processing apparatus;

FIGS. 22A and 22B are side views for explaining the operation of the substrate processing apparatus;

FIGS. 23A and 23B are side views for explaining the operation of the substrate processing apparatus;

FIGS. 24A and 24B are side views for explaining the operation of the substrate processing apparatus;

FIGS. 25A to 25C are side views for explaining the operation of the substrate processing apparatus;

FIGS. 26A to 26C are side views for explaining the operation of the substrate processing apparatus;

FIG. 27 is a bottom view mainly illustrating an extending/retracting mechanism included in a pitch converting unit holding a plurality of substrates that are aligned at an unequal pitch, in a second embodiment;

FIG. 28 is a bottom view mainly illustrating the extending/retracting mechanism included in the pitch converting unit holding a plurality of substrates that are aligned at a narrow pitch, in the second embodiment;

FIGS. 29A and 29B are side views for explaining an operation of a substrate processing apparatus according to a third embodiment;

FIGS. 30A and 30B are side views for explaining the operation of the substrate processing apparatus according to the third embodiment;

FIGS. 31A and 31B are side views for explaining the operation of the substrate processing apparatus according to the third embodiment; and

FIGS. 32A and 32B are side views for explaining the operation of the substrate processing apparatus according to the third embodiment.

### DETAILED DESCRIPTION

### First Embodiment

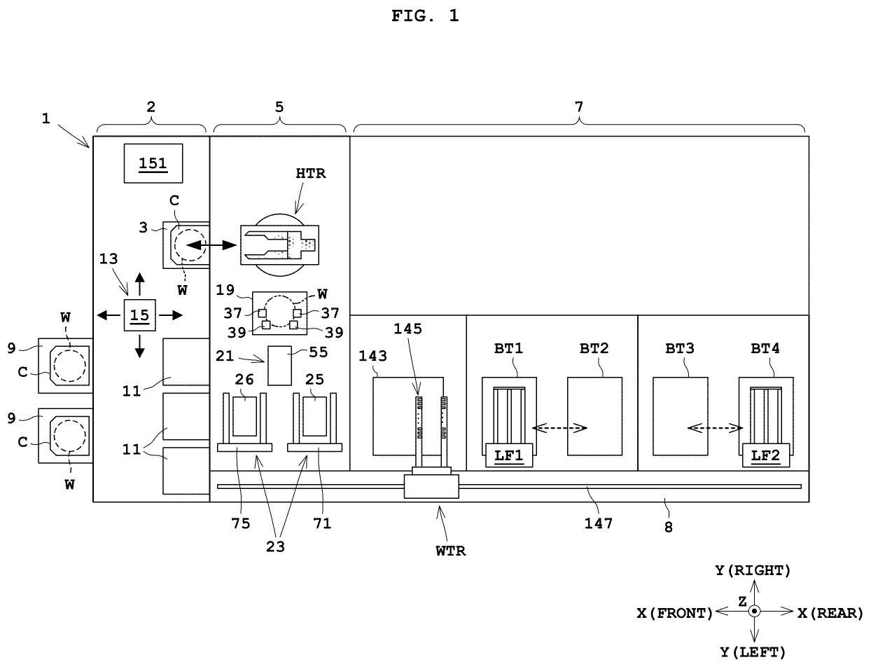

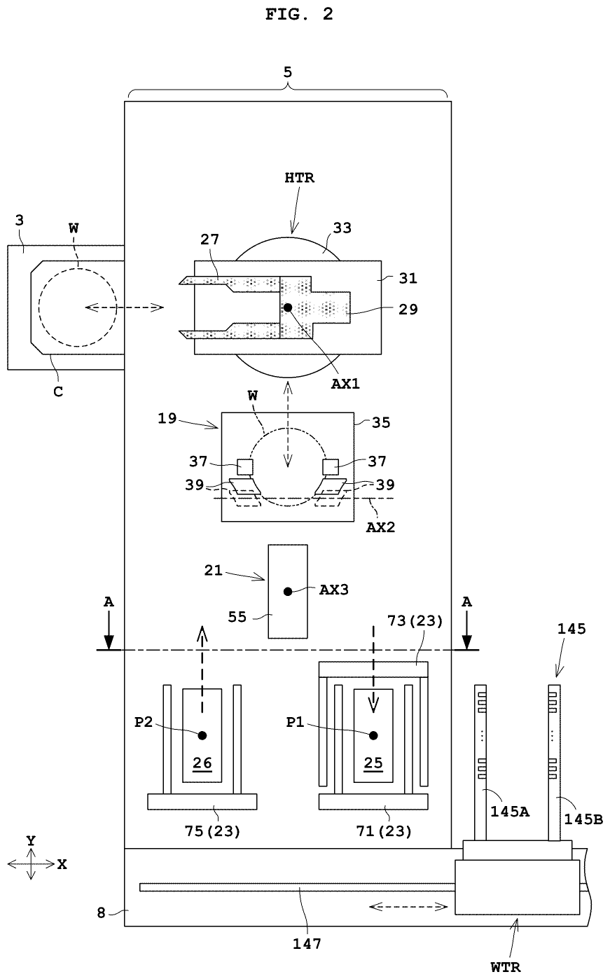

A first embodiment of the present invention will now be described with reference to drawings. FIG. 1 is a plan view illustrating a schematic configuration of a substrate processing apparatus 1 according to the first embodiment. FIG. 2 is a plan view illustrating a configuration of a transfer block 5 and elements around the transfer block 5.

In the description herein, for the convenience, the direction in which the transfer block 5 and a processing block 7 are arranged will be referred to as a “front-back direction X”. The front-back direction X is horizontal. In the front-back direction X, a direction from the processing block 7 toward the transfer block 5, for example, will be referred to as “frontwards”. The direction opposite to the frontward direction will be referred to as “rearwards”. The horizontal direction orthogonal to the front-back direction X will be referred to as “width directions Y”. One of the “width directions Y” will be referred to as “rightwards”, as appropriate. The direction opposite to the rightward direction will be referred to as “leftwards”. The direction perpendicular to the horizontal direction will be referred to as “vertical directions Z”. In each drawing, front, rear, right, left, top, and bottom are indicated as appropriate, for reference.

### <1. Configuration of Substrate Processing Apparatus>

FIG. 1 will now be referred to. The substrate processing apparatus 1 processes a substrate W. The substrate processing apparatus 1 is a batch substrate processing apparatus that processes a plurality of (e.g., fifty, seventy-five, or a hundred) substrates W as a batch. The substrate processing apparatus 1 performs processes such as a chemical liquid process, a cleaning process, and a drying process on the substrates W. The substrate processing apparatus 1 includes a stocker 2, a placing shelf 3, the transfer block 5, the processing block 7, and a batch substrate transporting area 8.

### <1-1. Stocker>

In the stocker 2, at least one carrier C is housed. The stocker 2 is positioned in front of the transfer block 5, adjacently. The carrier C stores therein a plurality of (e.g., twenty-five) substrates W, in the horizontal orientation, with a predetermined interval (e.g., 10 mm) therebetween. In other words, the carrier C stores N (e.g., twenty-five) substrates W aligned at a reference pitch, in the horizontal orientation. Note that N is a natural number equal to or more than two. In the reference pitch, a reference interval TN9 (e.g., 10 mm (millimeters)) is repeated. That is, when the reference interval TN9 is 10 mm, the reference pitch is 10-mm pitch. The N substrates W in the carrier C are aligned in the vertical direction Z, or a direction of the thickness of the substrates W. One example of the carrier C is a front opening unified pod (FOUP), but without limitation thereto.

The stocker 2 includes a plurality of (e.g., two) loading ports 9. The two loading ports 9 are arranged along the width direction Y. In the present embodiment, the two loading ports 9 are used for loading and unloading a carrier C. The stocker 2 also includes at least one storage shelf 11 and a carrier transporting robot 13. On the storage shelves 11, carriers C are placed.

The carrier transporting robot 13 transports the carrier C to and from the two loading ports 9, the storage shelf 11, and the placing shelf 3. The carrier transporting robot 13 has a gripper 15 that grips, for example, a protrusion provided on the top surface of the carrier C. The carrier transporting robot 13 can move the gripper 15 in the horizontal directions (the front-back direction X and the width direction Y) and the vertical direction Z. The carrier transporting robot 13 is driven by one or more electric motors.

The placing shelf 3 is disposed in the area of the stocker 2. The placing shelf 3 is positioned in front of the transfer block 5, adjacently. On the placing shelf 3, carriers C are placed. The placing shelf 3 corresponds to a carrier shelf according to the present invention.

### <1-2. Transfer Block>

FIGS. 1 and 2 will now be referred to. The transfer block 5 includes a substrate handling mechanism (robot) HTR, an orientation converting unit 19, a pusher mechanism 21, a delivering mechanism 23, and two pitch converting units 25, 26. The orientation converting unit 19 corresponds to an orientation converting mechanism according to the present invention. One of the two pitch converting units 25, 26 corresponds to a pitch converting unit according to the present invention.

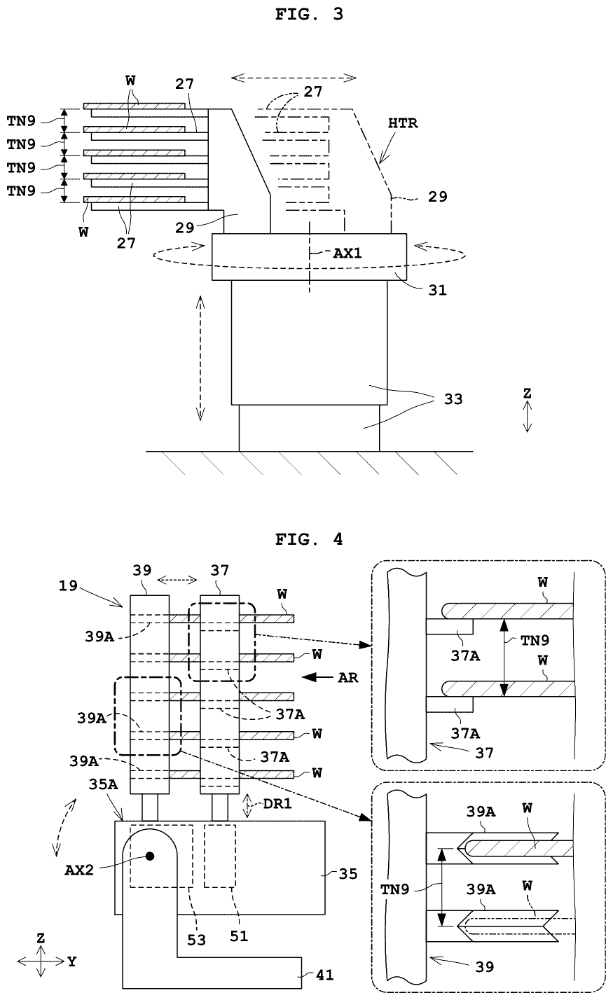

The substrate handling mechanism HTR is disposed on the rear side of the placing shelf 3. The substrate handling mechanism HTR transports a plurality of (e.g., twenty-five) substrates W in the horizontal orientation, between the carrier C placed on the placing shelf 3, and the orientation converting unit 19. As illustrated in FIG. 3, the substrate handling mechanism HTR includes a plurality of (e.g., twenty-five or thirteen) hands 27. Each of the hands 27 holds one substrate W. The plurality of hands 27 are arranged at the reference pitch, in the vertical direction Z. The twenty-five substrates W held by the twenty-five hands 27, for example, therefore, are aligned at the reference pitch. In the reference pitch, the reference interval TN9 (e.g., 10 mm) is repeated.

In FIG. 3 and the like, for the convenience of illustration, the substrate handling mechanism HTR includes five hands 27. It is assumed that a pair of horizontal holders 37 and a pair of vertical holders 39, to be described later, are configured to hold five substrates W. It is also assumed that a pusher member 55 (see FIG. 6), which is to be described later, is configured to support ten substrates W.

The substrate handling mechanism HTR further includes a hand support 29, an advancing/retracting unit 31, and a rotating lift 33. The hand support 29 supports the plurality of hands 27. The advancing/retracting unit 31 advances and retracts the hand support 29 to move the plurality of hands 27. The rotating lift 33 rotates the advancing/retracting unit 31 about a vertical axis AX1, to change the direction of the hands 27. The rotating lift 33 is fixed to a floor surface. Each of the advancing/retracting unit 31 and the rotating lift 33 includes an electric motor. The substrate handling mechanism HTR may also have a movable hand (not illustrated) for transporting only one substrate W, separately from the hands 27.

The orientation converting unit 19 converts a plurality of (e.g., twenty-five) substrates W to and from the vertical orientation from and to the horizontal orientation. The orientation converting unit 19 is disposed on the left side of the substrate handling mechanism HTR. As illustrated in FIG. 4, the orientation converting unit 19 includes a support base 35, the pair of horizontal holders 37, the pair of vertical holders 39, and a rotation driving unit 41.

The support base 35 is rotatably supported about a horizontal axis AX2 extending in the front-back direction X. The pair of horizontal holders 37 and the pair of vertical holders 39 are provided in a manner extending at a right angle with respect to a support surface 35A. When the plurality of substrates W are in the horizontal orientation, the pair of horizontal holders 37 holds the plurality of substrates W. In other words, when the plurality of substrates W are in the horizontal orientation, the plurality of substrates W are placed on the pair of horizontal holders 37. When the plurality of substrates W are in the vertical orientation, the pair of vertical holders 39 holds the plurality of substrates W.

The pair of horizontal holders 37 and the pair of vertical holders 39 are both disposed in the front-back direction X (see FIG. 2). When the pair of horizontal holders 37 holds the plurality of substrates W in the horizontal orientation, the pair of vertical holders 39 is at a position closer to the pusher mechanism 21 than to the pair of horizontal holders 37. The pair of horizontal holders 37 has a plurality of pairs (e.g. twenty-five pairs, thirty-eight pairs, fifty pairs) of shelves 37A that are arranged at the reference pitch, in a direction DR1 in which the pair of horizontal holders 37 extend. The pair of vertical holders 39 includes a plurality of pairs (e.g. twenty-five pairs, thirty-eight pairs, fifty pairs) of holding grooves 39A that are arranged at the reference pitch, in the direction DR1 in which the pair of vertical holders 39 extends.

The orientation converting unit 19 further includes an axial moving unit 51 and a housing moving unit 53. The axial moving unit 51 moves the pair of horizontal holders 37 along the direction DR1 in which the pair of horizontal holders 37 extends, by a preset extremely small distance. The housing moving unit 53 moves the pair of vertical holders 39 closer to or further away from the pair of horizontal holders 37. For example, when the pair of horizontal holders 37 is to hold a plurality of substrates W in the horizontal orientation, the housing moving unit 53 can move the pair of vertical holders 39 in the width direction Y. The rotation driving unit 41 converts the plurality of substrates W held by the pair of horizontal holders 37 and the pair of vertical holders 39 to and from the horizontal orientation from and to the vertical orientation.

The rotation driving unit 41 includes, for example, an electric motor. Each of the axial moving unit 51 and the housing moving unit 53 includes an air cylinder or an electric actuator. The electric actuator includes an electric motor.

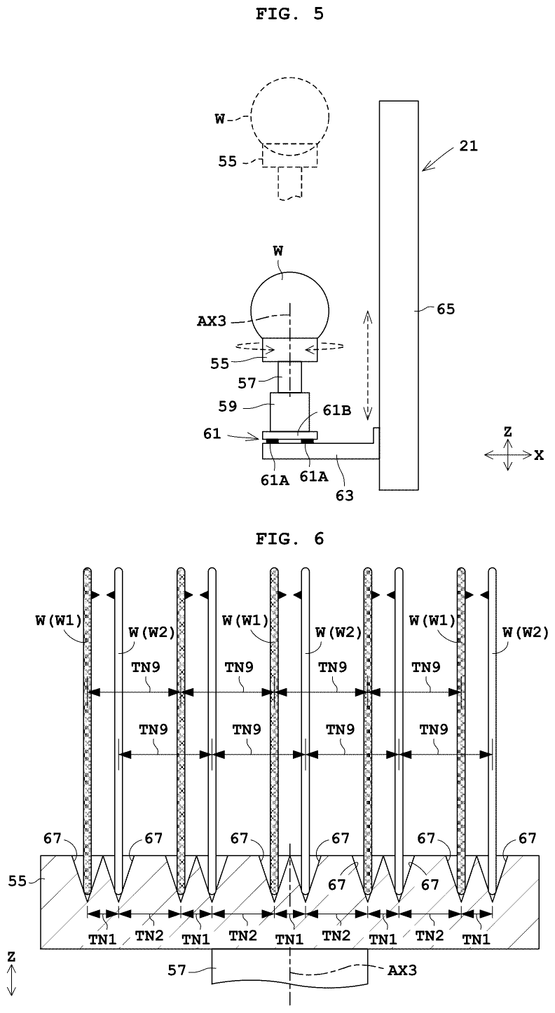

The pusher mechanism 21 is disposed on the left side of the orientation converting unit 19. As illustrated in FIG. 5, the pusher mechanism 21 includes a pusher member 55, a rotation shaft 57, a pusher rotating unit 59, a pusher horizontally moving unit 61, a lift stage 63, and a pusher lift 65.

As illustrated in FIG. 6, the pusher member 55 holds a plurality of (e.g., fifty, seventy-five, or a hundred) substrates W that are aligned at the unequal pitch in which a first interval TN1 (e.g., 3.333 mm) and a second interval TN2 (e.g., 6.666 mm) are repeated alternately, in the vertical orientation. The second interval TN2 is an interval larger than the first interval TN1 (second interval TN2>first interval TN1). The first interval TN1 is also referred to as a narrow interval, and the second interval TN2 is also referred to as a wide interval.

As illustrated in FIG. 6, the pusher member 55 includes a plurality of (e.g., fifty, seventy-five, or a hundred) vertical holding grooves 67 for holding a plurality of substrates W in the vertical orientation. The plurality of vertical holding grooves 67 are arranged, for example, at the unequal pitch in which the first interval TN1 and the second interval TN2 are repeated alternately. The sum of the first interval TN1 (e.g., 3.333 mm) and the second interval TN2 (e.g., 6.666 mm) equals the reference interval TN9 (e.g., 10 mm).

FIG. 5 will now be referred to. A bottom surface of the pusher member 55 is connected to an upper end of the rotation shaft 57. The pusher rotating unit 59 rotates the pusher member 55 and the rotation shaft 57 about the vertical axis AX3 passing through the rotation shaft 57. As a result, the plurality of substrates W supported in the vertical orientation on the pusher member 55 are rotated about the vertical axis AX3. The pusher rotating unit 59 includes an electric motor, for example. The pusher rotating unit 59 is provided under the pusher member 55. The pusher rotating unit 59 is also attached to the top surface of the lift stage 63 with the pusher horizontally moving unit 61 therebetween.

The pusher horizontally moving unit 61 includes two guide rails 61A extending in the width direction Y, a slider 61B, and an electric motor, not illustrated. The two guide rails 61A are provided on the top surface of the lift stage 63. The slider 61B is caused to move in the width direction Y along the two guide rails 61A. The slider 61B is driven by the electric motor. The pusher lift 65 raises and lowers the lift stage 63 in the vertical direction Z. With this, the pusher member 55 is raised and lowered. The pusher lift 65 includes, for example, an electric actuator.

FIG. 2 will now be referred to. The two pitch converting units 25, 26 are disposed on the left side of the pusher mechanism 21. If the two pitch converting units 25, 26 are to be arranged in the vertical direction Z, the substrate processing apparatus 1 becomes unnecessarily high. In this respect, the two pitch converting units 25, 26 are arranged in the front-back direction X. In other words, the first pitch converting unit 25 is disposed on the rear side of the second pitch converting unit 26 in plan view. Therefore, it is possible to suppress the substrate processing apparatus 1 from becoming unnecessarily high. For example, the delivering mechanism 23 transports a plurality of substrates W aligned at the unequal pitch to and from the pusher member 55 from and to the two pitch converting units 25, 26.

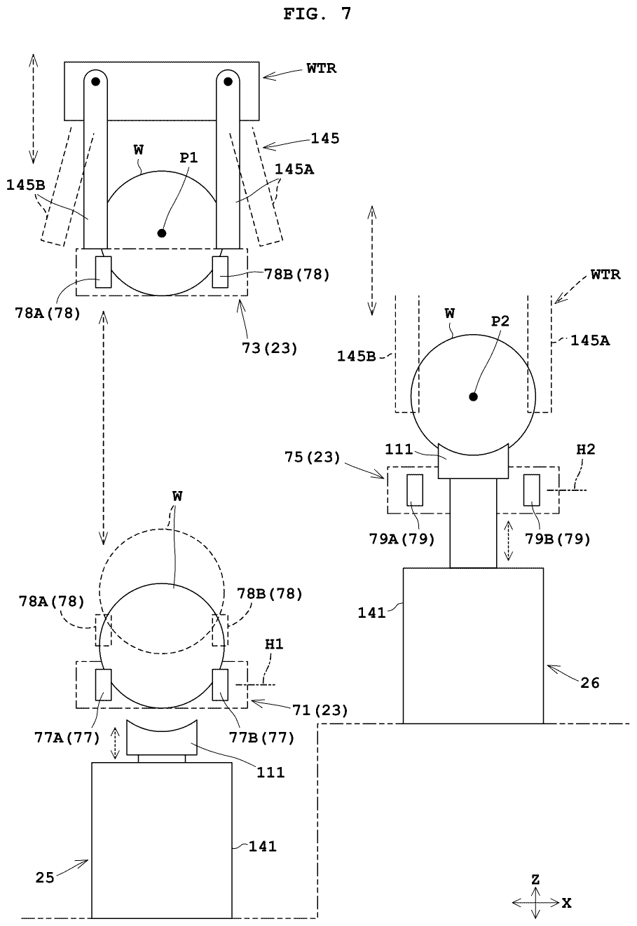

FIGS. 2 and 7 will now be referred to. FIG. 7 is a side view illustrating elements such as the delivering mechanism 23 and two pitch converting units 25, 26, in a view as indicated by arrows A-A in FIG. 2. The delivering mechanism 23 includes an incoming delivering mechanism 71, an intermediating mechanism 73, and an outgoing delivering mechanism 75. The incoming delivering mechanism 71 transports the plurality of substrates W aligned at the unequal pitch, from the pusher member 55 to the first pitch converting unit 25. The intermediating mechanism 73 transports the plurality of substrates W aligned at the narrow pitch, from the first pitch converting unit 25 to a first delivery position P1. The outgoing delivering mechanism 75 transports the plurality of substrates W aligned at the unequal pitch, from the second pitch converting unit 26 onto the pusher member 55. The incoming delivering mechanism 71, the intermediating mechanism 73, and the outgoing delivering mechanism 75 have a chuck 77, a chuck 78, and a chuck 79, respectively.

As illustrated in FIG. 7, the incoming delivering mechanism 71 is disposed at an incoming delivery height H1. The incoming delivering mechanism 71 is disposed, for example, beside a lift 141 of the second pitch converting unit 26. The chuck 78 of the intermediating mechanism 73 is provided at a position above the first pitch converting unit 25. The chuck 78 of the intermediating mechanism 73 is disposed between the incoming delivery height H1 and a first delivery position P1. The first delivery position P1 is a position higher than the incoming delivery height H1 and an outgoing delivery height H2. The outgoing delivering mechanism 75 is disposed at the outgoing delivery height H2 higher than the incoming delivery height H1. Each of the incoming delivering mechanism 71 and the outgoing delivering mechanism 75 is configured in such a manner that the plurality of substrates W held by the outgoing delivering mechanism 75 and the outgoing delivering mechanism 75 do not interfere with the plurality of other substrates W held by the incoming delivering mechanism 71 and the incoming delivering mechanism 71.

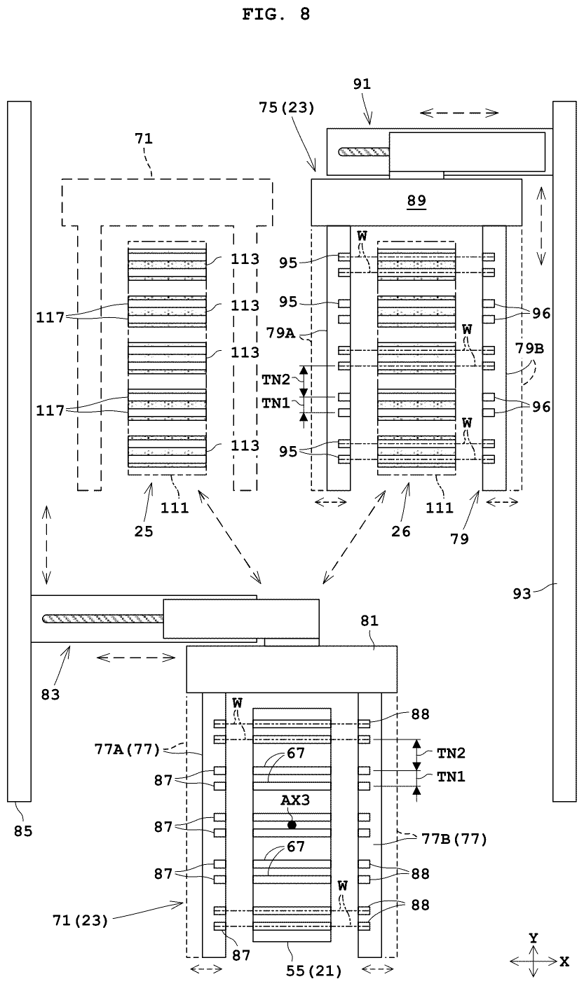

FIG. 8 is a plan view mainly illustrating the incoming delivering mechanism 71 and the outgoing delivering mechanism 75. The incoming delivering mechanism 71 is disposed on the rear side of the outgoing delivering mechanism 75. That is, the incoming delivering mechanism 71 is disposed on side of the processing block 7, and the outgoing delivering mechanism 75 is disposed on the side of the stocker 2. The incoming delivering mechanism 71 includes the chuck 77, an opening and closing unit 81, a front-back direction moving unit 83, and a width direction moving unit 85.

The chuck 77 holds a plurality of substrates W that are aligned at the unequal pitch, in the vertical orientation. The chuck 77 includes a pair of chuck members 77A, 77B extending in the width direction Y. The pair of chuck members 77A, 77B includes a plurality of pairs (e.g., fifty pairs, seventy-five pairs, a hundred pairs) of holding grooves 87, 88 that are arranged at the unequal pitch. In the unequal pitch, the first interval TN1 (e.g., 3.333 mm) and the second interval TN2 (e.g., 6.666 mm) are repeated alternately. The first chuck member 77A has a plurality of holding grooves 87 that are arranged at the unequal pitch. The second chuck member 77B has a plurality of holding grooves 88 that are arranged at the unequal pitch.

The opening and closing unit 81 supports the two chuck members 77A, 77B in a manner movable in the front-back direction X. The opening and closing unit 81 opens or closes the two chuck members 77A, 77B with respect to each other in the front-back direction X. Specifically, the opening and closing unit 81 brings the two chuck members 77A, 77B close to each other or further away from each other. When the opening and closing unit 81 closes the chuck 77, the chuck 77 can hold the plurality of substrates W in the vertical orientation. By contrast, when the opening and closing unit 81 opens the chuck 77, the chuck 77 can pass the plurality of substrates W in the vertical orientation between the two chuck members 77A, 77B, in the vertical direction Z. The opening and closing unit 81 includes an air cylinder or an electric actuator that drives the two chuck members 77A, 77B.

The front-back direction moving unit 83 is disposed nearer to the two pitch converting units 25, 26 than the width direction moving unit 85. The front-back direction moving unit 83 moves the chuck 77 and the opening and closing unit 81 horizontally in the front-back direction X. The width direction moving unit 85 moves the chuck 77, the opening and closing unit 81, and the front-back direction moving unit 83 horizontally in the width direction Y. That is, the front-back direction moving unit 83 and the width direction moving unit 85 can move the chuck 77 in the front-back direction X and the width direction Y (two-dimensional directions). The front-back direction moving unit 83 includes, for example, an air cylinder or an electric actuator. The width direction moving unit 85 includes an electric actuator.

The outgoing delivering mechanism 75 includes the chuck 79, an opening and closing unit 89, a front-back direction moving unit 91, and a width direction moving unit 93. The chuck 79 has the same configuration as that of the chuck 77. Specifically, the chuck 79 includes a pair of chuck members 79A, 79B extending in the width direction Y. The pair of chuck members 79A, 79B includes a plurality of pairs (e.g., fifty pairs, seventy-five pairs, a hundred pairs) of holding grooves 95, 96 that are arranged at the unequal pitch. The front-back direction moving unit 91 is disposed nearer to the two pitch converting units 25, 26 than the width direction moving unit 93. Other than the configurations described above, the opening and closing unit 89, the front-back direction moving unit 91, and the width direction moving unit 93 are configured in the same manner as the opening and closing unit 81, the front-back direction moving unit 83, and the width direction moving unit 85, respectively.

FIG. 9 is a plan view mainly illustrating the intermediating mechanism 73. The intermediating mechanism 73 includes the chuck 78, an opening and closing unit 101, an arm 103, and a lift 105. The chuck 78 includes a pair of chuck members 78A, 78B extending in the width direction Y. The pair of chuck members 78A, 78B includes a plurality of pairs (e.g., fifty pairs, seventy-five pairs, a hundred pairs) of holding grooves 107, 108 arranged at the narrow pitch (e.g., 3.333-mm pitch (⅓ pitch)). Specifically, the first chuck member 78A has a plurality of holding grooves 107 that are arranged at the narrow pitch, in the width direction Y. The second chuck member 78B has a plurality of holding grooves 108 that are arranged at the narrow pitch.

The opening and closing unit 101 is provided on the right side (on the side of the pusher mechanism 21) of the chuck 78. Other than this point, the opening and closing unit 101 is configured in the same manner as the opening and closing unit 81. More specifically, the opening and closing unit 101 supports the pair of chuck members 78A, 78B in a manner movable in the front-back direction X. The opening and closing unit 101 opens or closes the pair of chuck members 78A, 78B in the front-back direction X. When the opening and closing unit 101 closes the chuck 78, the chuck 78 can hold a plurality of substrates W in the vertical orientation aligned at in the narrow pitch. By contrast, when the opening and closing unit 101 opens the chuck 78, the chuck 78 can pass the plurality of substrates W in the vertical orientation between the two chuck members 78A, 78B, in the vertical direction Z.

The opening and closing unit 101 is attached to the lift 105, with the arm 103 therebetween, in a manner enabled to move up or and down. The lift 105 raises and lowers the chuck 78 and the opening and closing unit 101 in the vertical directions Z. The lift 105 includes, for example, an electric actuator. With this, the intermediating mechanism 73 can receive the plurality of substrates W aligned at the narrow pitch in the vertical orientation, from the first pitch converting unit 25, and move the plurality of substrates W to the first delivery position P1 (see FIG. 7), to deliver the plurality of substrates W to the main transporting mechanism WTR.

Note that the transfer block 5 has two transporting paths for transporting a plurality of substrates W to and from the pusher member 55 (pusher mechanism 21) from and to the main transporting mechanism WTR. That is, a first transporting path is a path passing through the incoming delivering mechanism 71, the first pitch converting unit 25, and the intermediating mechanism 73. A second conveyance path is a path passing through the second pitch converting unit 26 and the outgoing delivering mechanism 75. For example, when fifty substrates W are held by the intermediating mechanism 73, the outgoing delivering mechanism 75 can transport the fifty substrates W having been processed in a chemical liquid processing bath BT1, for example, to the pusher member 55. The fifty substrates W (processing substrate group) can therefore be transported smoothly.

### <1-2-1. Pitch Converting Unit>

FIG. 7 and FIGS. 10 to 13 will now be referred to. Each of the two pitch converting units 25, 26 converts the pitch of the plurality of substrates W to and from the unequal pitch from and to the narrow pitch. In the unequal pitch, the first interval TN1 (e.g., 3.333 mm) and second interval TN2 (e.g., 6.666 mm) wider than the first interval TN1 are repeated alternately. In the narrow pitch, the first interval TN1 is repeated.

The first pitch converting unit 25 aligns a plurality of substrates W aligned at the unequal pitch, at the narrow pitch. That is, the first pitch converting unit 25 converts the pitch of the plurality of substrates W before being processed in the processing block 7, to the narrow pitch. By contrast, the second pitch converting unit 26 causes the plurality of substrates W aligned at the narrow pitch, to become aligned at the unequal pitch. That is, the second pitch converting unit 26 converts the pitch of the plurality of substrates W having been processed in the processing block 7, to the unequal pitch.

Each of the two pitch converting units 25, 26 includes a pitch converting body 111. The pitch converting body 111 includes a plurality of (e.g., twenty-five, thirty-eight, and fifty) holding members 113 and a moving unit 115.

The plurality of holding members 113 hold the plurality of substrates W aligned at the unequal pitch, in the vertical orientation. Each of the plurality of holding members 113 has two holding grooves 117 that hold two substrates W, respectively, among the plurality of substrates W. The two holding grooves 117 are spaced apart from each other by the first interval TN1 (e.g., 3.333 mm). On each of the holding members 113, the two holding grooves 117 are arranged in the width direction Y. For example, when the pitch converting unit 25 has twenty-five holding members 113, the twenty-five holding members 113 can hold fifty substrates W in the fifty holding grooves 117, respectively. In FIGS. 10 to 13, for the convenience of illustration, each of the two pitch converting units 25, 26 are illustrated as having five holding members 113 (113A to 113E).

The moving unit 115 moves the plurality of holding members 113 in the alignment direction of the plurality of substrates W (width direction Y) to shift the plurality of holding members 113 between an unequal pitch arrangement in which the plurality of substrates W are aligned at the unequal pitch, and a narrow pitch arrangement in which the plurality of substrates W are aligned at the narrow pitch. The moving unit 115 includes a base member 119, two guide rails 121, an extending/retracting mechanism 123, a driving unit 125, and a coupling portion 127.

The two guide rails 121 support the plurality of holding members 113 in a manner movable in the alignment direction (width direction Y). Each of the two guide rails 121 extends in the width direction Y. The two guide rails 121 are attached to the top surface of the base member 119. Among the plurality of holding members 113, the holding member 113C at the center is fixed to the base member 119 using a screw SW, for example. That is, the holding member 113C at the center does not move in the width direction Y. Note that the number of the guide rails 121 is not limited to two, and may be one or three or more. That is, the moving unit 115 may include one or more guide rails 121.

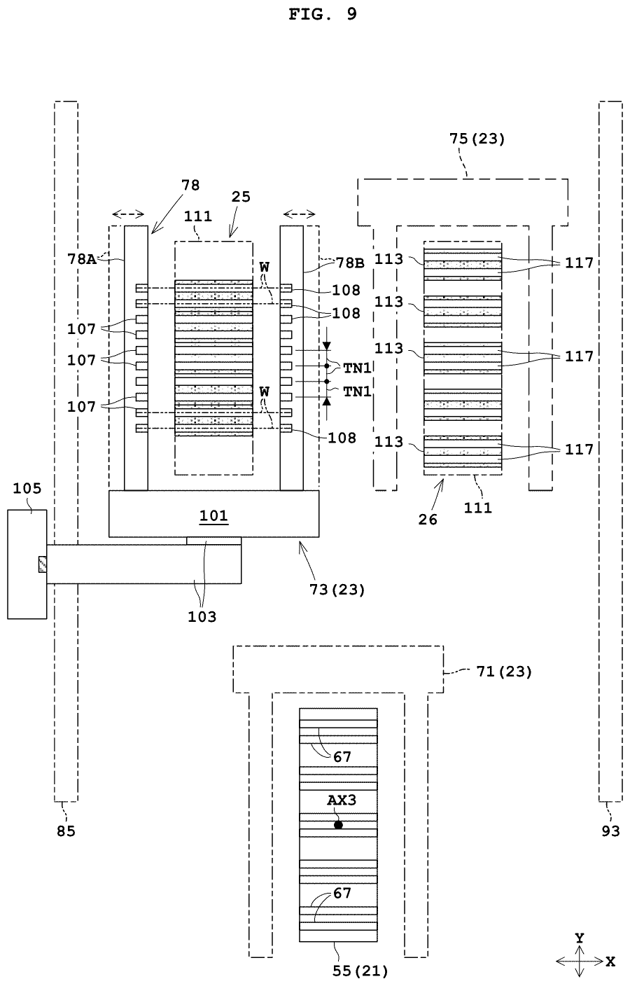

The extending/retracting mechanism 123 causes the plurality of holding members 113 to extend and to retract in the alignment direction (width direction Y). The extending/retracting mechanism 123 is connected to each of the holding members 113. The extending/retracting mechanism 123 is provided as, for example, a link mechanism. Specifically, the extending/retracting mechanism 123 is configured as, for example, a lazy tongs mechanism, a linear zigzag mechanism, or any mechanism similar thereto. The extending/retracting mechanism 123 includes, for example, a plurality of (twenty-five; five in FIG. 10 and other drawings) link members 129, a plurality of (twenty-five; five in FIG. 10 and other drawings) pins 131, and a plurality of (twenty-four; four in FIG. 10 and other drawings) joints 133. In FIGS. 12 and 13, for example, the five pins 131 are provided to the bottom surfaces of the five holding members 113, respectively. Each of the five link members 129 is attached to one of the five pins 131, in a manner rotatable about a vertical axis. The five pins 131 are positioned at the five centers of the five link members 129, respectively. Each of the four joints 133 connects ends of two adjacent link members 129.

For example, a joint 133A connects a first end of the link member 129B and a second end of the link member 129A. A joint 133B connects a second end of the link member 129B and a first end of the link member 129C.

The driving unit 125 drives the extending/retracting mechanism 123. The driving unit 125 is attached to the bottom surface of the base member 119. The driving unit 125 causes a rod 125A extending in the width direction Y to extend and to retract. The driving unit 125 includes an air cylinder or an electric actuator. The coupling portion 127 couples the holding member 113E at the end of the plurality of holding members 113, to a distal end of the rod 125A of the driving unit 125. The coupling portion 127 is passed through an opening 119A of the base member 119.

In FIGS. 10 and 12, for example, when the rod 125A of the driving unit 125 is extended, the extending/retracting mechanism 123 causes the holding member 113E at the end to move away from the holding member 113C at the center, to cause the other three holding members 113A, 113B, and 113D to move away from the holding member 113C at the center. As a result, the plurality of substrates W becomes aligned at the unequal pitch. In FIGS. 11 and 13, for example, when the rod 125A of the driving unit 125 is retracted, the extending/retracting mechanism 123 causes the holding member 113E at the end to move closer to the holding member 113C at the center, to cause the other three holding members 113A, 113B, and 113D to move closer to the holding member 113C at the center. As a result, the plurality of substrates W becomes aligned at the narrow pitch (first interval TN1).

As illustrated in FIG. 7, each of the pitch converting units 25, 26 includes a lift 141. The lift 141 raises and lowers the pitch converting body 111 (the plurality of holding members 113 and the moving unit 115). The lift 141 includes an air cylinder or an electric actuator.

The lift 141 of the first pitch converting unit 25 raises and lowers the plurality of holding members 113, between an upper position higher than (the top surface of) the chuck 77 of the incoming delivering mechanism 71, and a lower position lower than the chuck 77. Furthermore, the lift 141 of the second pitch converting unit 26 raises and lowers the plurality of holding members 113 between an upper position higher than (the upper surface of) the chuck 79 of the outgoing delivering mechanism 75 and a lower position lower than the chuck 79.

### <1-3. Processing Block>

FIG. 1 will now be referred to. The processing block 7 includes a plurality of (e.g., four) batch processing baths BT1 to BT4 and a drying unit 143. The four batch processing baths BT1 to BT4 and the drying unit 143 are arranged in the front-back direction X in which the substrate processing apparatus 1 extends. In each of the four batch processing baths BT1 to BT4, a plurality of (e.g. fifty, seventy-five, or a hundred) substrates W are immersed as a batch. Each of the four batch processing baths BT1 to BT4 stores therein a process liquid (e.g., chemical liquid or pure water) in which the plurality of substrates W are immersed.

The four batch processing baths BT1 to BT4 include, for example, two chemical liquid processing baths BT1, BT3 and two cleaning processing baths BT2, BT4. The chemical liquid processing bath BT1 and the cleaning processing bath BT2 together form one set, and the chemical liquid processing bath BT3 and the cleaning processing bath BT4 together forms another set. The combinations of the chemical liquid processing bath and the cleaning processing bath is not limited to this example. The number of batch processing baths is not limited to four, and may be one or more. At least one of the four batch processing baths BT1 to BT4 corresponds to the substrate processing unit according to the present invention.

Each of the two chemical liquid processing baths BT1, BT3 performs etching processing using a chemical liquid. For example, a solution of phosphoric acid is used as the chemical liquid, but the chemical liquid is not limited to the phosphoric acid solution. The chemical liquid is heated to a preset temperature. A chemical liquid ejecting pipe (not illustrated) is provided on an inner bottom surface of each of the chemical liquid processing baths BT1, BT3. Each of the chemical liquid processing baths BT1, BT3 stores therein a chemical liquid supplied from the chemical liquid ejecting pipe.

Each of the two cleaning processing baths BT2, BT4 performs a cleaning process, for cleaning the chemical liquid attached to the plurality of substrates W with cleaning liquid (rinsing liquid). As the cleaning liquid, pure water such as deionized water (DIW) is used, for example. Each of the cleaning processing baths BT2, BT4 stores therein pure water supplied from a pure water ejection pipe, not illustrated.

The processing block 7 includes a lifter LF1 as a dedicated transport mechanism for transferring the substrates W subjected to the chemical liquid process in the chemical liquid processing bath BT1 to the cleaning processing bath BT2, and a lifter LF2 for transferring the substrates W subjected to the chemical liquid process in the chemical liquid processing bath BT3 to the cleaning processing bath BT4. Each of the two lifters LF1, LF2 includes a substrate holding unit that holds a plurality of (e.g., fifty, seventy-five, a hundred) substrates W aligned in the width direction Y at the narrow pitch, in the vertical orientation, a lift that raises and lowers the substrate holding unit, and a horizontally moving unit that moves the substrate holding unit in the front-back direction X.

The drying unit 143 includes a substrate holding mechanism that holds a plurality of (e.g., fifty, seventy-five, or a hundred) substrates W aligned at the narrow pitch in the width direction Y, in the vertical orientation, and a processing chamber that houses the plurality of substrates W held by the substrate holding mechanism. The drying unit 143 dries the substrates by supplying an organic solvent (e.g., isopropyl alcohol) to the substrates W in a reduced-pressure atmosphere, or getting rid of the liquid components on the surface of the substrate W using centrifugal force.

### <1-4. Batch Substrate Transporting Area>

The batch substrate transporting area 8 is positioned on the rear side of the stocker 2, and is positioned adjacently on the left side the transfer block 5 and the processing block 7. The batch substrate transporting area 8 extends in the front-back direction X. The batch substrate transporting area 8 includes a main transporting mechanism (main transporting robot) WTR. The main transporting mechanism WTR transports a plurality of (e.g., fifty, seventy-five, or a hundred) substrates W aligned in the width direction Y in the vertical orientation at the narrow pitch, in the front-back direction X. The main transporting mechanism WTR transports a plurality of substrates W from and to the first delivery position P1, the second delivery position P2, a plurality of (for example, four) batch processing baths BT1 to BT4, and the drying unit 143.

The main transporting mechanism WTR includes a chuck 145, a chuck lift (not illustrated), a chuck horizontally moving unit (not illustrated), and a guide rail 147. The chuck 145 holds a plurality of substrates W aligned at the narrow pitch in the width direction Y, in the vertical orientation. The chuck 145 includes a pair of chuck members 145A, 145B that extend in the width direction Y. The pair of chuck members 145A, 145B includes a plurality of pairs (e.g. fifty pairs, seventy-five pairs, or a hundred pairs) of holding grooves that are arranged along the width direction Y, at the narrow pitch. The pair of chuck members 145A, 145B is opened and closed by a chuck opening and closing unit, not illustrated.

The chuck 145 is movable in the front-back direction X along the guide rail 147. The chuck 145 is moved in the front-back direction X by the chuck horizontally moving unit. The chuck 145 is moved up and down in the vertical direction Z by the chuck lift. Each of the chuck horizontally moving unit and the chuck lift includes, for example, an electric actuator. The chuck opening and closing unit includes, for example, an air cylinder or an electric actuator.

### <1-5. Control Unit>

The substrate processing apparatus 1 includes a control unit 151 (see FIG. 1) and a storage unit (not illustrated). The control unit 151 controls each of the components included in the substrate processing apparatus 1. The control unit 151 includes one or more processors such as a central processing unit (CPU). The storage unit includes at least one of a read-only memory (ROM), a random access memory (RAM), and a hard disk, for example. The storage unit stores therein a computer program required in controlling each of the components included in the substrate processing apparatus 1.

### <2. Operation of Substrate Processing Apparatus>

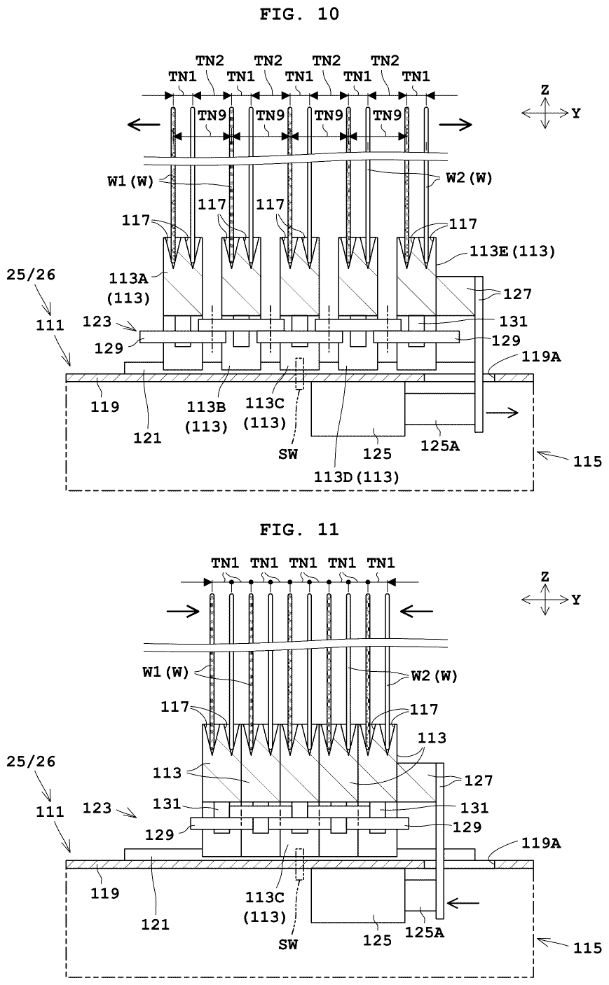

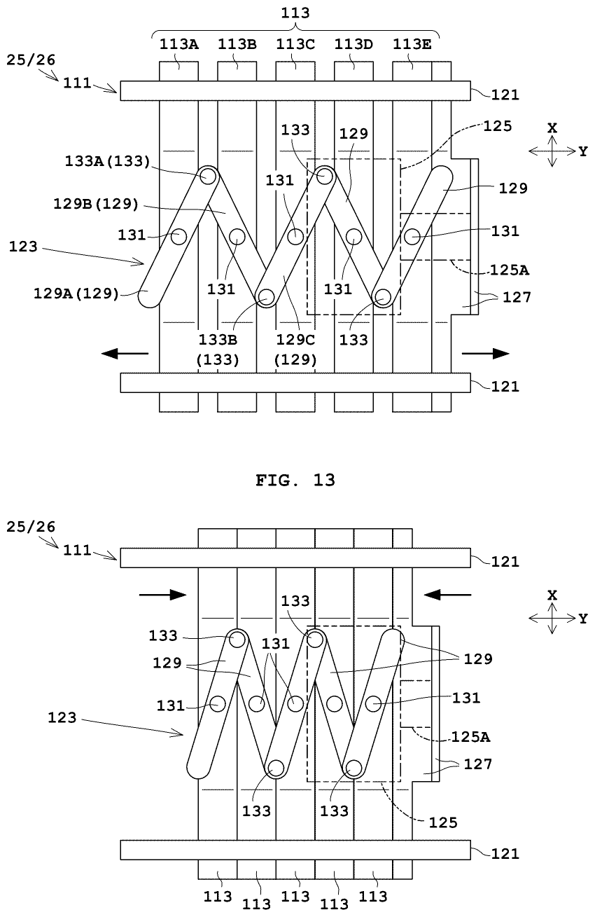

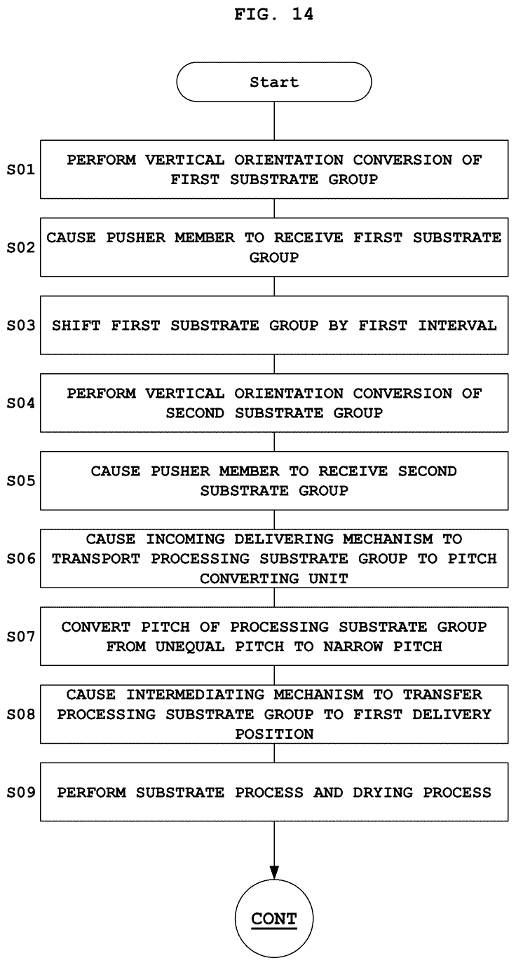

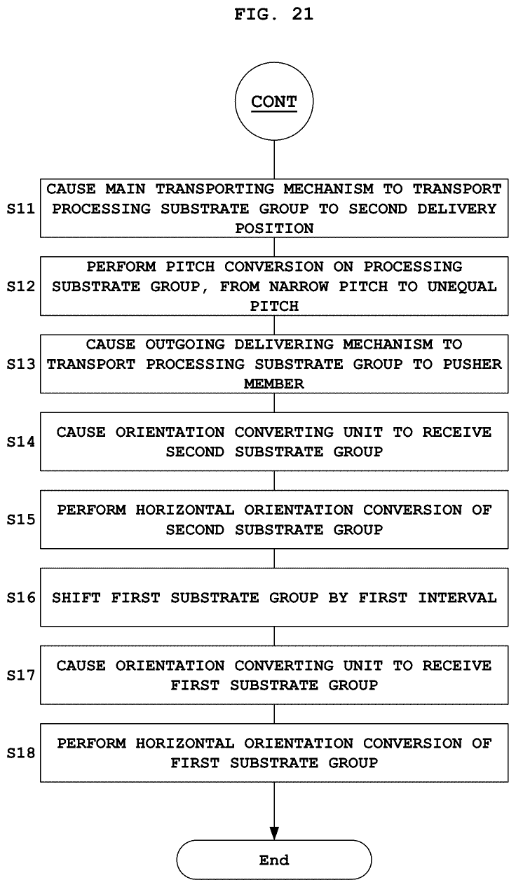

An operation of the substrate processing apparatus 1 will now be described with reference to the flowchart illustrated in FIGS. 14 and 21. To begin with, a former half of the operation, from transporting the carrier C to the loading port 9 to drying will be described with reference to FIG. 14. In the present embodiment, the substrate processing apparatus 1 processes fifty substrates W taken out from the two carriers C, as a batch.

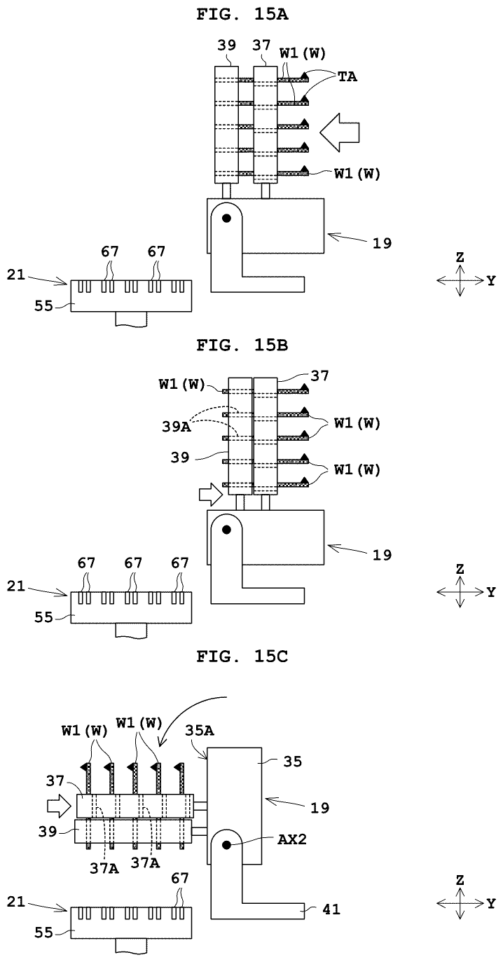

In FIG. 15A and the like, the reference numeral TA denotes a front surface (a device surface or a principal surface) of a substrate W (W1, W2). The rear surface of a substrate W is a surface opposite to the front surface of the substrate W. The device surface is a surface on which a device is formed, or a surface in the middle of the process of forming a device. Note that, in FIG. 15A and the like, for the convenience of illustration, the twenty-five substrates W1 are represented as five substrates W1, and the twenty-five substrates W2 are represented as five substrates W2.

### [Step S01] Perform Vertical Orientation Conversion of First Substrate Group

FIG. 1 will now be referred to. An external transporting robot, not illustrated, transports two carriers C onto the loading ports 9, respectively, one after another. The carrier transporting robot 13 of the stocker 2 then transports the first carrier C from the loading port 9 onto the placing shelf 3. It is assumed herein that the first carrier C houses the twenty-five substrates W1 (first substrate group) that are aligned at the reference pitch (e.g., 10-mm pitch), in which the reference interval TN9 is repeated. The substrate handling mechanism HTR in the transfer block 5 takes out the twenty-five substrates W1 in the horizontal orientation, from the first carrier C placed on the placing shelf 3 using twenty-five hands 27, for example. The substrate handling mechanism HTR then transports the twenty-five substrates W1 having been taken out, to the orientation converting unit 19. Note that the carrier transporting robot 13 moves the empty first carrier C, where the twenty-five substrates W1 have been taken out, from the placing shelf 3 to the storage shelf 11.

FIG. 15A will now be referred to. The orientation converting unit 19 receives the twenty-five substrates W1 aligned at the reference pitch, from the substrate handling mechanism HTR. In the orientation converting unit 19, the twenty-five substrates W1 are held (placed) on the twenty-five pairs of shelves 37A, respectively, provided to the pair of horizontal holders 37. FIG. 15B will now be referred to. The housing moving unit 53 (see FIG. 4) of the orientation converting unit 19 brings the pair of vertical holders 39 closer to the pair of horizontal holders 37. As a result, the peripheral edges of the twenty-five substrates W1 are housed and held inside the twenty-five pairs of holding grooves 39A of the pair of vertical holders 39, respectively.

FIG. 15C will now be referred to. The orientation converting unit 19 then converts the orientation of the twenty-five substrates W1 (first substrate group) held at the reference pitch, from the horizontal orientation to the vertical orientation, as a batch. Specifically, the rotation driving unit 41 included in the orientation converting unit 19 converts the twenty-five substrates W1 held by the pair of horizontal holders 37 and the pair of vertical holders 39, from the horizontal orientation to the vertical orientation. The axial moving unit 51 (see FIG. 4) of the orientation converting unit 19 then moves the pair of horizontal holders 37 in a direction in which the pair of horizontal holders 37 move closer to the support surface 35A so that the twenty-five pairs of shelves 37A on the pair of horizontal holders 37 move away from the twenty-five substrates W1 that are in the vertical orientation.

### [Step S02] Cause Pusher Member to Receive First Substrate Group

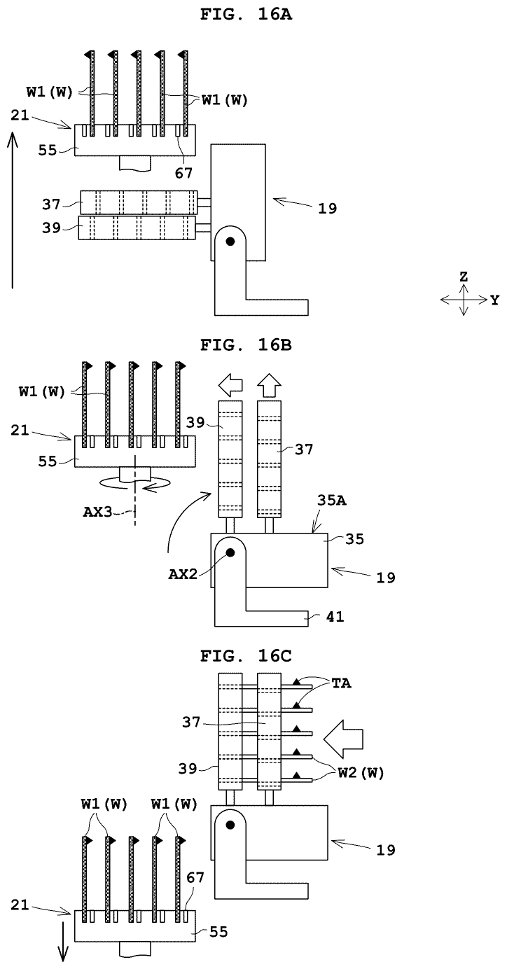

FIG. 16A will now be referred to. The pusher lift 65 (see FIG. 5) in the pusher mechanism 21 raises the pusher member 55 to a position higher than the pair of horizontal holders 37 and the pair of vertical holders 39. As a result, the pusher member 55 receives the twenty-five substrates W1 (first substrate group) having the orientation converted to the vertical orientation. The pusher member 55 holds the twenty-five substrates W1 aligned at the reference pitch, in the vertical orientation. Note that the fifty vertical holding grooves 67 of the pusher member 55 are arranged at the unequal pitch.

### [Step S03] Shift First Substrate Group by First Interval

FIG. 16B will now be referred to. The pusher mechanism 21 shifts the twenty-five substrates W1 held by the pusher member 55 by the first interval TN1 (3.333 mm), in the alignment direction of the twenty-five substrates W1. Specifically, the pusher rotating unit 59 (see FIG. 5) of the pusher mechanism 21 rotates the pusher member 55 by 180 degrees about the vertical axis AX3. As a result, the twenty-five substrates W1 held by the pusher member 55 are shifted leftwards by the first interval TN1. The direction in which the front surfaces of the twenty-five substrates W1 face is changed from the left to the right. Note that the substrates W1 may also be moved by the first interval TN1 by causing the pusher rotating unit 59 to rotate the pusher member 55 by 180 degrees, and by causing the pusher horizontally moving unit 61 (see FIG. 5) to move the pusher member 55 in the width direction Y.

The orientation converting unit 19 also rotates the elements such as the pair of horizontal holders 37 by 90 degrees about the horizontal axis AX2. As a result, the elements such as the pair of horizontal holders 37 are raised. The axial moving unit 51 (see FIG. 4) in the orientation converting unit 19 moves the pair of horizontal holders 37 in the direction moving the pair of horizontal holders 37 away from the support surface 35A. The housing moving unit 53 (see FIG. 4) in the orientation converting unit 19 moves the pair of vertical holders 39 away from the pair of horizontal holders 37.

### [Step S04] Perform Vertical Orientation Conversion of Second Substrate Group

The carrier transporting robot 13 illustrated in FIG. 1 then transports a second carrier C from the loading port 9 onto the placing shelf 3. It is assumed herein that the second carrier C houses the twenty-five substrates W2 that are aligned at the reference pitch (10-mm pitch), in the same manner as the first carrier C. The substrate handling mechanism HTR takes out the twenty-five substrates W2 in the horizontal orientation, from the second carrier C placed on the placing shelf 3, using twenty-five hands 27. The substrate handling mechanism HTR then transports the taken out twenty-five substrates W2 to the orientation converting unit 19. Note that the carrier transporting robot 13 moves the empty second carrier C from which the twenty-five substrates W2 have been taken out, from the placing shelf 3 to the storage shelf 11.

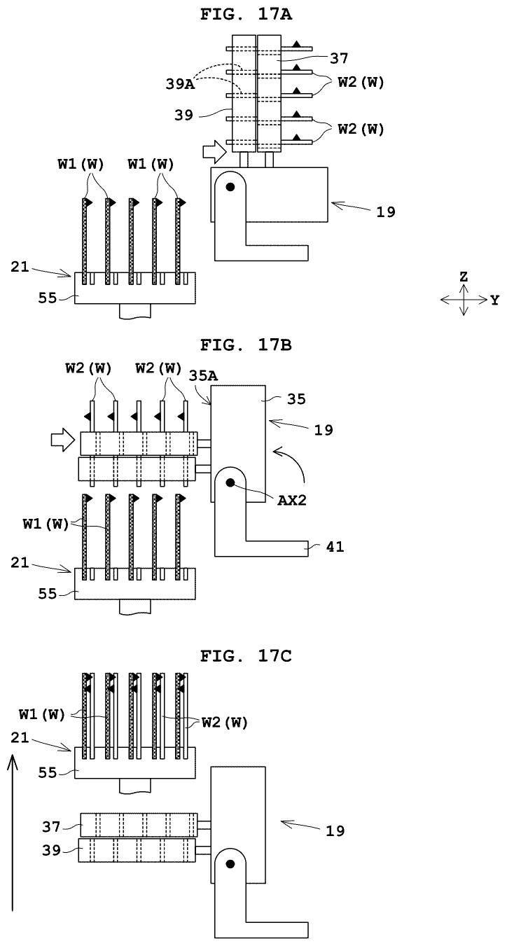

FIG. 16C will now be referred to. The orientation converting unit 19 receives the twenty-five substrates W2 aligned at the reference pitch, from the substrate handling mechanism HTR. In the orientation converting unit 19, the twenty-five substrates W2 are held on the twenty-five pairs of shelves 37A, respectively, provided to the pair of horizontal holders 37. FIG. 17A will now be referred to. The housing moving unit 53 (see FIG. 4) of the orientation converting unit 19 then brings the pair of vertical holders 39 closer to the pair of horizontal holders 37.

FIG. 17B will now be referred to. The orientation converting unit 19 then converts the orientation of the twenty-five substrates W2 (second substrate group) held at the reference pitch, from the horizontal orientation to the vertical orientation, as a batch. The axial moving unit 51 (see FIG. 4) of the orientation converting unit 19 then moves the pair of horizontal holders 37 in a direction in which the pair of horizontal holders 37 move closer to the support surface 35A so that the twenty-five pairs of shelves 37A on the pair of horizontal holders 37 move away from the twenty-five substrates W1 that are in the vertical orientation.

### [Step S05] Cause Pusher Member to Receive Second Substrate Group

FIG. 17C will now be referred to. The pusher lift 65 (see FIG. 5) in the pusher mechanism 21 then raises the pusher member 55 to a position higher than the pair of horizontal holders 37 and the pair of vertical holders 39. As a result, the pusher member 55 receives the twenty-five substrates W2 (second substrate group) having the orientation converted to the vertical orientation. The pusher member 55 holds the fifty substrates W (W1, W2) aligned at the unequal pitch. In the fifty substrates W, the twenty-five substrates W1 and the twenty-five substrates W2 are positioned alternately.

As illustrated in FIGS. 17B and 17C, the front surfaces (the device surfaces or the main surfaces) of the twenty-five substrates W1 face a predetermined direction (rightwards). By contrast, the front surfaces of the twenty-five substrates W2 face the direction opposite to the predetermined direction (leftwards). That is, the fifty substrates W are arranged in a manner what is called face to face.

### [Step S06] Cause Incoming Delivering Mechanism to Transport Processing Substrate Group to Pitch Converting Unit

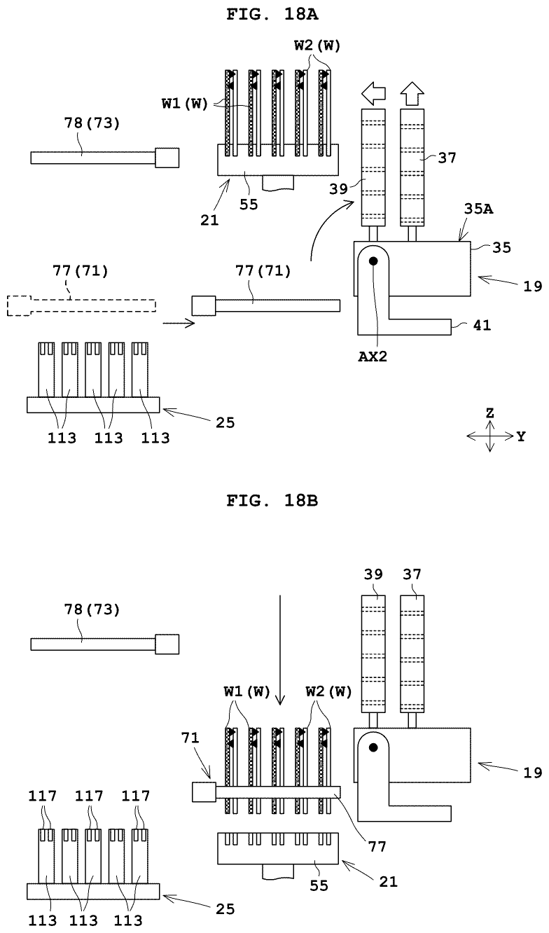

The incoming delivering mechanism 71 then transports the fifty substrates W (processing substrate group) aligned at the unequal pitch, from the pusher member 55 to the first pitch converting unit 25. This operation will now be explained specifically. FIG. 18A will now be referred to. To begin with, the orientation converting unit 19 rotates the elements such as the pair of horizontal holders 37 by 90 degrees about the horizontal axis AX2. As a result, the elements such as the pair of horizontal holders 37 are raised. The incoming delivering mechanism 71 moves the chuck 77 horizontally, from the position above the first pitch converting unit 25 to the position below the pusher member 55. The chuck 77 is closed and is capable of holding fifty substrates W.

FIG. 18B will now be referred to. The pusher mechanism 21 then lowers the pusher member 55 holding the fifty substrates W in the vertical orientation. As the pusher member 55 is passed between the pair of chuck members 77A, 77B of the chuck 77, the fifty substrates W are delivered from the pusher member 55 to the chuck 77. The chuck 77 then holds fifty substrates W that are aligned at the unequal pitch in the vertical orientation.

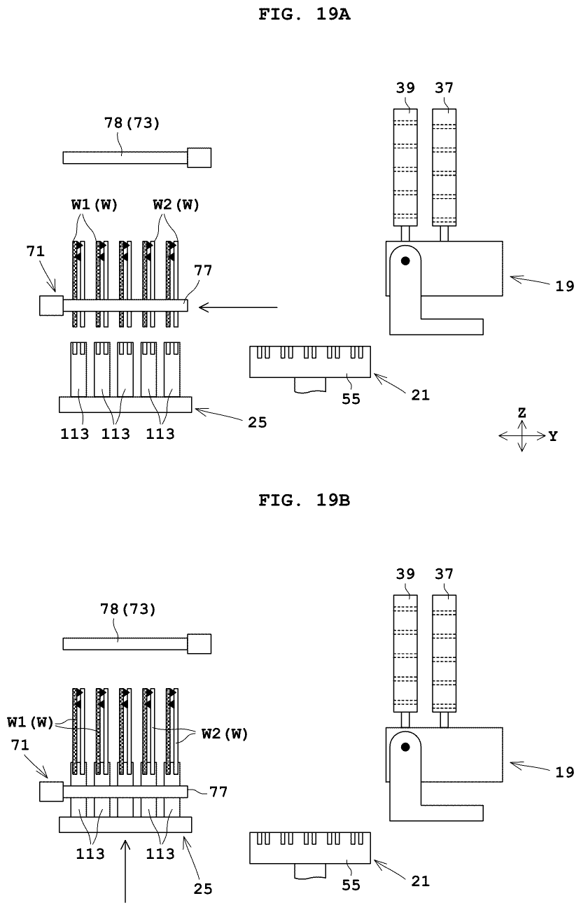

FIG. 19A will now be referred to. The incoming delivering mechanism 71 then moves the chuck 77 from the position above the pusher member 55 to the position above the first pitch converting unit 25. FIG. 19B will now be referred to. The lift 141 (see FIG. 7) of the first pitch converting unit 25 then raises the pitch converting body 111 including the twenty-five holding members 113. As a result, the first pitch converting unit 25 receives the fifty substrates W from the incoming delivering mechanism 71.

[Step S07] Convert Pitch of Processing Substrate Group from Unequal Pitch to Narrow Pitch

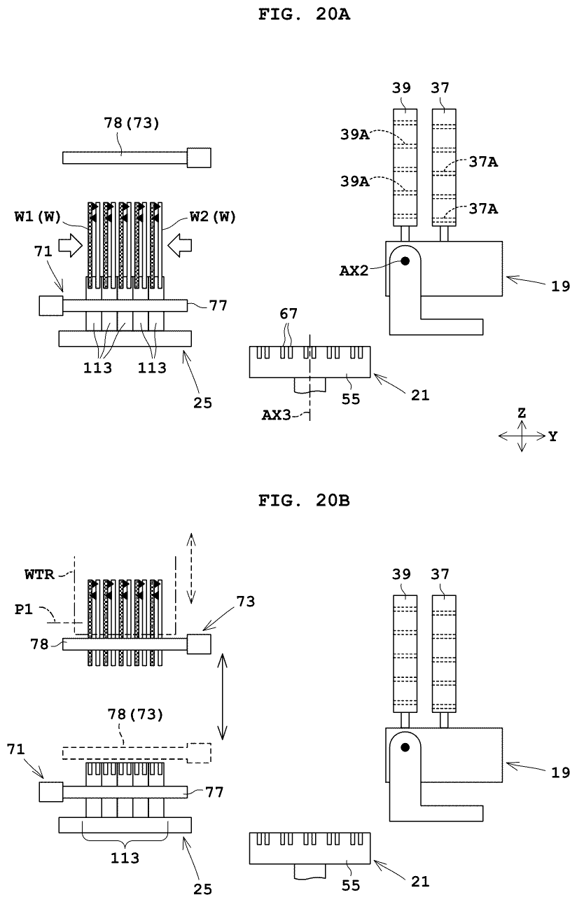

FIG. 20A will now be referred to. The first pitch converting unit 25 then converts the pitch of the fifty substrates W from the unequal pitch to the narrow pitch (3.333-mm pitch). In other words, the first pitch converting unit 25 aligns the fifty substrates W having been aligned at the unequal pitch, at the narrow pitch. This operation will now be explained specifically.

Each of the twenty-five holding members 113 in the first pitch converting unit 25 has two holding grooves 117 that are spaced apart from each other by the first interval TN1 (3.333 mm). The first pitch converting unit 25 holds two substrates W1, W2, among the fifty substrates W, using the two holding grooves 117 on each of the twenty-five holding members 113, and holds the fifty substrates W aligned at the unequal pitch, using the twenty-five holding members 113.

The moving unit 115 (see FIG. 10) of the first pitch converting unit 25 then moves the twenty-five holding members 113 in the alignment direction of the fifty substrates W (the width direction Y) to switch the fifty substrate W from the unequal pitch arrangement in which the substrates W are aligned at the unequal pitch, to the narrow pitch arrangement in which the fifty substrates W are aligned at the narrow pitch. The intermediating mechanism 73 keeps the chuck 78 open.

### [Step S08] Cause Intermediating Mechanism to Transfer Processing Substrate Group to First Delivery Position

FIG. 20B will now be referred to. The intermediating mechanism 73 then lowers the chuck 78 as indicated by the broken line, to receive the fifty substrates W aligned at the narrow pitch held by the first pitch converting unit 25. The intermediating mechanism 73 then closes the chuck 78. In this manner, chucks 78 is enabled to hold fifty substrates W.

The intermediating mechanism 73 then raises the chuck 78 to the first delivery position P1. In this manner, the intermediating mechanism 73 can receive fifty substrates W from the first pitch converting unit 25, and deliver the fifty substrates W to the main transporting mechanism WTR. The chuck 78 holds fifty substrates W that are aligned at the narrow pitch in the vertical orientation.

### [Step S09] Perform Substrate Process and Drying Process

The main transporting mechanism WTR then receives fifty substrates W from the intermediating mechanism 73, using the chuck 145, and transports the fifty substrates W to one of the two chemical liquid processing baths BT1, BT3. For example, when the main transporting mechanism WTR transports fifty substrates W to the chemical liquid processing bath BT1, the lifter LF1 receives the fifty substrates W that are aligned at the narrow pitch, from the main transporting mechanism WTR, at the position above the chemical liquid processing bath BT1. Then, by lowering the fifty substrates W, the lifter LF1 immerses the fifty substrates W in the chemical liquid stored in the chemical liquid processing bath BT1. As a result, the fifty substrates W are subjected to the chemical liquid process, as a batch.

After a preset chemical liquid process time has elapsed, the lifter LF1 pulls out the fifty substrates W from the chemical liquid in the chemical liquid processing bath BT1 by raising the fifty substrates W. The lifter LF1 then moves the fifty substrates W horizontally from the position above the chemical liquid processing bath BT1 to the position above the cleaning processing bath BT2. Then, by lowering the fifty substrates W, the lifter LF1 immerses the fifty substrates W in the pure water stored in the cleaning processing bath BT2. As a result, the fifty substrates W are cleaned as a batch. After a preset cleaning processing time has elapsed, the lifter LF1 pulls out the fifty substrates W from the pure water in the cleaning processing bath BT2.

When the main transporting mechanism WTR transports the fifty substrates W to the chemical liquid processing bath BT3, the lifter LF2 receives the fifty substrates W from the main transporting mechanism WTR. The lifter LF2 then transports the fifty substrates W to the chemical liquid processing bath BT3, and to the cleaning processing bath BT4, sequentially.

After the cleaning process, the main transporting mechanism WTR receives the fifty substrates W from one of the two lifters LF1, LF2, using the chuck 145, and transports the fifty substrates W to the drying unit 143. The drying unit 143 dries the fifty substrates W. The main transporting mechanism WTR then receives the fifty dried substrates W from the drying unit 143.

The latter half of the operation from the drying process to transporting to the carrier C from the loading port 9 will be described with reference to FIG. 21.

### [Step S11] Cause Main Transporting Mechanism to Transport Processing Substrate Group to Second Delivery Position

FIGS. 2 and 22A will now be referred to. The main transporting mechanism WTR transports the fifty substrates W in the vertical orientation having been processed in the chemical liquid processing bath BT1, or the like, and aligned at the narrow pitch, to a position above the second pitch converting unit 26. In other words, the main transporting mechanism WTR transports the fifty substrates W having been subjected to the drying process by the drying unit 143, to a position above the second pitch converting unit 26.

The main transporting mechanism WTR then lowers the fifty substrates W being held by the chuck 145, to the second delivery position P2. In this manner, the main transporting mechanism WTR transports the fifty substrates W in the vertical orientation that are aligned at the narrow pitch, to the second pitch converting unit 26. The second pitch converting unit 26 receives the fifty substrates W in the vertical orientation that are aligned at the narrow pitch, from the main transporting mechanism WTR. Before receiving the fifty substrates W, the second pitch converting unit 26 moves the twenty-five holding members 113 in such a manner that the fifty holding grooves 117 are arranged at the narrow pitch.

[Step S12] Perform Pitch Conversion on Processing Substrate Group, from Narrow Pitch to Unequal Pitch

FIG. 22B will now be referred to. The second pitch converting unit 26 then converts the pitch of the fifty substrates W from the narrow pitch to the unequal pitch. This operation will now be explained specifically. The second pitch converting unit 26 holds the fifty substrates W that are aligned at the narrow pitch, using the twenty-five holding members 113, while ensuring the first interval TN1 between two of substrates W using the two holding grooves 117 provided to each of the twenty-five holding members 113 and spaced apart from each other by the first interval TN1. The moving unit 115 (see FIG. 10) then moves the twenty-five holding members 113 in the alignment direction of the fifty substrates W (in the width direction Y), so as to shift the fifty substrates W from the narrow pitch arrangement to the unequal pitch arrangement.

### [Step S13] Cause Outgoing Delivering Mechanism to Transport Processing Substrate Group to Pusher Member

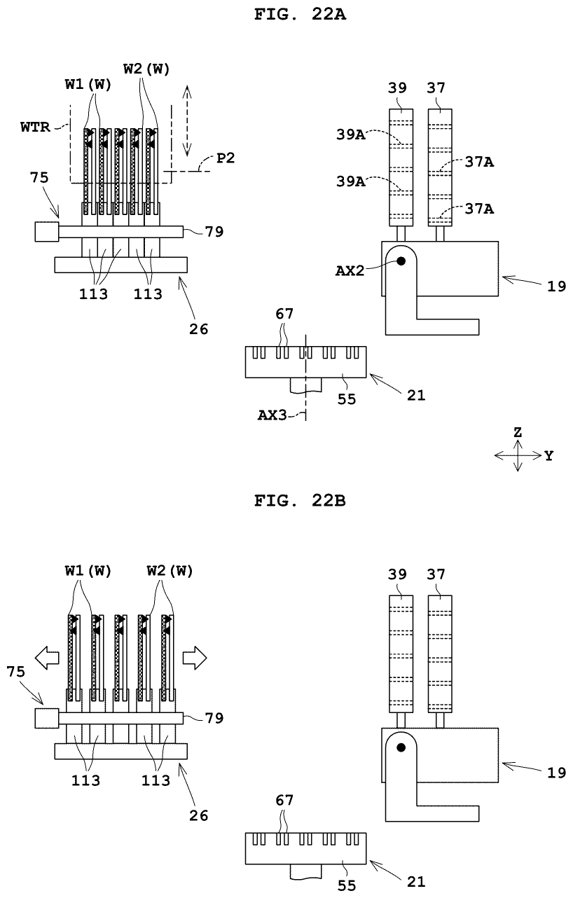

FIG. 23A will now be referred to. The outgoing delivering mechanism 75 of the delivering mechanism 23 then transports the fifty substrates W that are aligned at the unequal pitch in the vertical orientation, from the second pitch converting unit 26 to the pusher member 55. This operation will now be explained specifically. The chuck 79 of the outgoing delivering mechanism 75 is closed. To begin with, the lift 141 (see FIG. 7) of the second pitch converting unit 26 lowers the pitch converting body 111 including the twenty-five holding members 113. As the holding members 113 are lowered, the outgoing delivering mechanism 75 receives the fifty substrates W in the vertical orientation and aligned at the unequal pitch, and holds the substrates W, using the chuck 79.

FIG. 23B will now be referred to. The outgoing delivering mechanism 75 then transports the fifty substrates W being held by the chuck 79, from the position above the second pitch converting unit 26 to the position above the pusher member 55. The pusher mechanism 21 then raises the pusher member 55 to a position higher than the chuck 79. As the pusher member 55 is raised, the pusher mechanism 21 receives the fifty substrates W from the chuck 79 of the outgoing delivering mechanism 75, and holds the substrates W, using the pusher member 55. The pusher member 55 holds the fifty substrates W that are aligned at the unequal pitch, in the vertical orientation.

### [Step S14] Cause Orientation Converting Unit to Receive Second Substrate Group

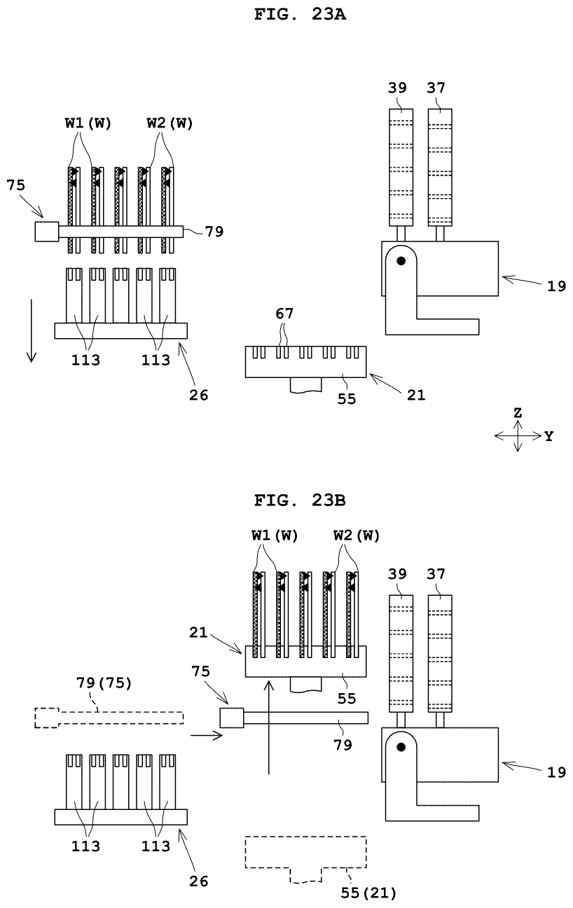

FIG. 24A will now be referred to. The outgoing delivering mechanism 75 moves the chuck 79 to a position above the second pitch converting unit 26. The rotation driving unit 41 in the orientation converting unit 19 then rotates the elements including the pair of horizontal holders 37 by 90 degrees about the horizontal axis AX2 so as to enable the pair of vertical holders 39 to receive the twenty-five substrates W2 (second substrate group). As a result, the pair of horizontal holders 37 and the pair of vertical holders 39 are laid down. The axial moving unit 51 brings the pair of horizontal holders 37 closer to the support surface 35A, and the housing moving unit 53 brings the pair of vertical holders 39 closer to the pair of horizontal holders 37.

FIG. 24B will now be referred to. The pusher mechanism 21 then lowers the pusher member 55 from a position higher than the pair of vertical holders 39, to a position lower than the pair of vertical holders 39. As the pusher member 55 is lowered, the orientation converting unit 19 receives the twenty-five substrates W2 (second substrate group), among the fifty substrates W (processing substrate group), from the pusher member 55, using the pair of horizontal holders 37 and the pair of vertical holders 39. The pair of vertical holders 39 holds the twenty-five substrates W2 that are aligned at the reference pitch (10-mm pitch). The axial moving unit 51 then moves the pair of horizontal holders 37 away from the support surface 35A. As a result, the twenty-five pairs of shelves 37A on the pair of horizontal holders 37 come into contact with the rear surfaces of the twenty-five substrates W2, respectively.

Note that, as illustrated in FIG. 24A, the moving unit 115 in the second pitch converting unit 26 moves twenty-five (twenty-four) holding members 113 in such a manner that the fifty holding grooves 117 are arranged at the narrow pitch. Furthermore, as illustrated in FIG. 24B, the lift 141 in the second pitch converting unit 26 raises the pitch converting body 111 including the twenty-five holding members 113 in such a manner that the fifty holding grooves 117 are arranged at a position higher than the chuck 79.

### [Step S15] Perform Horizontal Orientation Conversion of Second Substrate Group

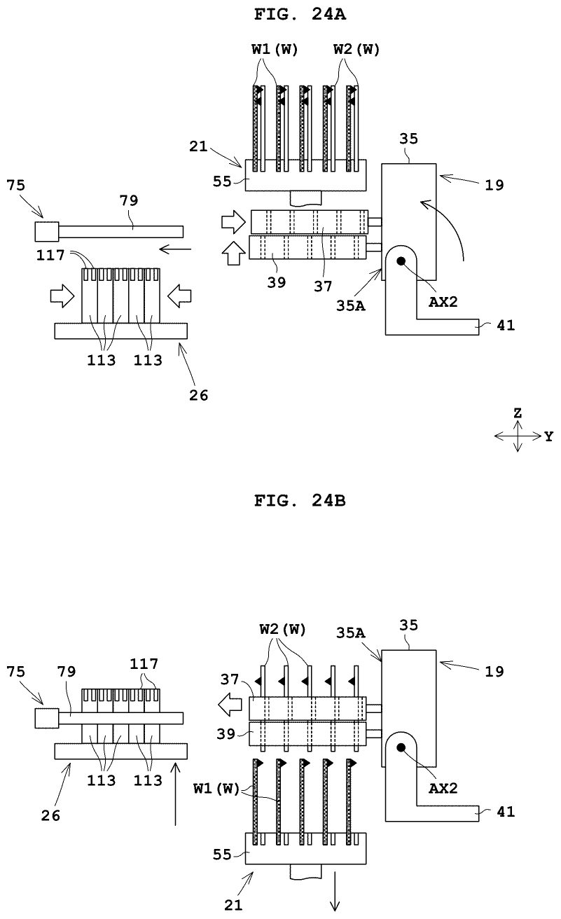

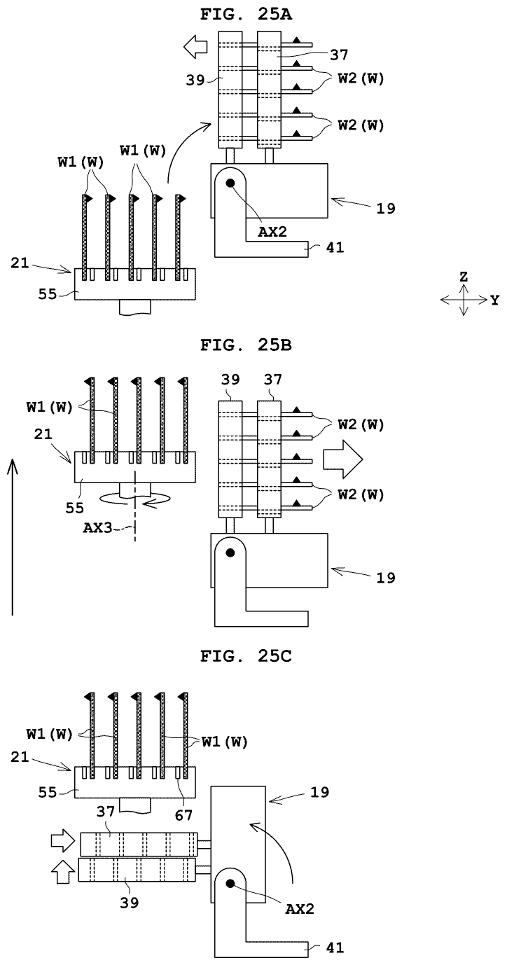

FIG. 25A will now be referred to. The orientation converting unit 19 rotates the elements such as the pair of horizontal holders 37 by 90 degrees about the horizontal axis AX2. In this manner, the orientation converting unit 19 converts the twenty-five substrates W2 from the vertical orientation to the horizontal orientation. The housing moving unit 53 then moves the pair of vertical holders 39 away from the pair of horizontal holders 37. As a result, the peripheral edges of the twenty-five substrates W2 are removed from the twenty-five pairs of holding grooves 39A in the pair of vertical holders 39.

The carrier transporting robot 13 illustrated in FIG. 1 transports the empty second carrier C from the storage shelf 11 to the placing shelf 3. The substrate handling mechanism HTR takes out the twenty-five substrates W2 having the orientation converted into the horizontal orientation by the orientation converting unit 19 and aligned at the reference pitch, from the orientation converting unit 19 (see FIG. 25B). The substrate handling mechanism HTR then transports the twenty-five substrates W2 into the second carrier C on the placing shelf 3. The carrier transporting robot 13 then transports the second carrier C storing therein the processed twenty-five substrates W2, from the placing shelf 3 to the loading port 9.

### [Step S16] Shift First Substrate Group by First Interval

FIG. 25B will now be referred to. After the orientation converting unit 19 changes the orientation of the twenty-five substrates W2 to the horizontal orientation, the pusher mechanism 21 raises the pusher member 55 holding the twenty-five substrates W1 (first substrate group).

The pusher mechanism 21 also shifts the twenty-five substrates W1 held by the pusher member 55 by the first interval TN1 (3.333 mm) in the alignment direction of the twenty-five substrates W1. Specifically, the pusher rotating unit 59 (see FIG. 5) of the pusher mechanism 21 rotates the pusher member 55 by 180 degrees about the vertical axis AX3. As a result, the twenty-five substrates W1 held by the pusher member 55 are shifted rightwards by the first interval TN1. The direction in which the front surfaces of the twenty-five substrates W1 face is also changed from the right to the left. Note that the substrates W1 may also be moved by the first interval TN1 by causing the pusher rotating unit 59 to rotate the pusher member 55 by 180 degrees, and by causing the pusher horizontally moving unit 61 (see FIG. 5) to move the pusher member 55 in the width direction Y.

### [Step S17] Cause Orientation Converting Unit to Receive First Substrate Group

FIG. 25C will now be referred to. The orientation converting unit 19 lays down the pair of horizontal holders 37 and the pair of vertical holders 39. The axial moving unit 51 then brings the pair of horizontal holders 37 closer to the support surface 35A, and the housing moving unit 53 brings the pair of vertical holders 39 closer to the pair of horizontal holders 37.

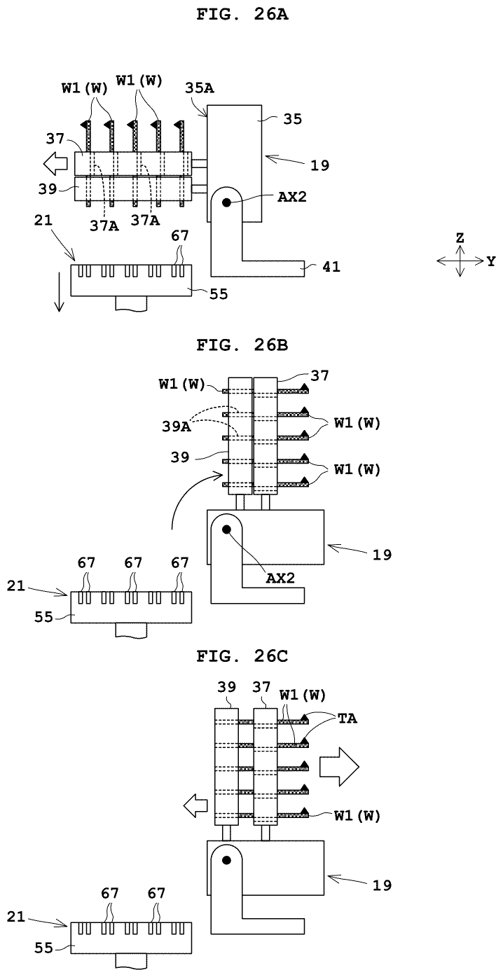

FIG. 26A will now be referred to. The pusher mechanism 21 then lowers the pusher member 55 from a position higher than the pair of vertical holders 39, to a position lower than the pair of vertical holders 39. As the pusher member 55 is lowered, the orientation converting unit 19 receives the twenty-five remaining substrates W1 from the pusher member 55, using the pair of horizontal holders 37 and the pair of vertical holders 39. The pair of vertical holders 39 holds the twenty-five substrates W1 that are aligned at the reference pitch (e.g., 10-mm pitch). The axial moving unit 51 then brings twenty-five pairs of shelves 37A of the pair of horizontal holders 37 into contact with the rear surfaces of the twenty-five substrates W1, respectively.

### [Step S18] Perform Horizontal Orientation Conversion of First Substrate Group

FIG. 26B will now be referred to. The orientation converting unit 19 rotates the elements such as the pair of horizontal holders 37 by 90 degrees about the horizontal axis AX2. In this manner, the orientation converting unit 19 converts the twenty-five substrates W1 from the vertical orientation to the horizontal orientation. FIG. 26C will now be referred to. The housing moving unit 53 then moves the pair of vertical holders 39 away from the pair of horizontal holders 37.

The carrier transporting robot 13 illustrated in FIG. 1 transports the empty first carrier C from the storage shelf 11 to the placing shelf 3. The substrate handling mechanism HTR takes out the twenty-five substrates W1 having the orientation converted into the horizontal orientation by the orientation converting unit 19 and aligned at the reference pitch (10-mm pitch), from the orientation converting unit 19 (see FIG. 26C). The substrate handling mechanism HTR then transports the twenty-five substrates W1 into the first carrier C on the placing shelf 3. The carrier transporting robot 13 then transports the first carrier C storing therein the processed twenty-five substrates W1, from the placing shelf 3 to the loading port 9. The external transporting robot, not illustrated, transports the two carriers C from the respective loading ports 9, to the next destination, one after another.

According to the present embodiment, each of the pitch converting units 25, 26 includes the plurality of holding members 113 that hold the plurality of substrates W aligned at the unequal pitch, and the moving unit 115 that moves the plurality of holding members 113 in the alignment direction (width direction Y) so as to change between the unequal pitch arrangement in which the plurality of substrates W are aligned at the unequal pitch and the narrow pitch arrangement in which the plurality of substrates W are aligned at the narrow pitch. Each of the plurality of holding members 113 has two holding grooves 117 that hold two substrates W, respectively, among the plurality of substrates W. The two holding grooves 117 are spaced apart from each other by the first interval TN1 (first interval TN1<second interval TN2). Because each of the holding members 113 has the two holding grooves 117 for holding the two substrates W, respectively, each of the holding members 113 can be provided with a relatively large width in the direction in which of the plurality of substrates W are aligned (width direction Y). With this, it becomes possible to ensure the dimensional accuracy of the holding members 113, and to allow the plurality of holding members 113 to hold the substrates W in the vertical orientation, easily.

Furthermore, the two holding grooves 117 of each of the holding members 113 are spaced apart from each other by the first interval TN1 (e.g., 3.333 mm), which is an interval that is a half of the second interval TN2 (e.g., 6.666 mm). In the unequal pitch, the first interval TN1 and the second interval TN2 wider than the first interval TN1 are repeated alternately. Let us assume herein that there is a predetermined interval (reference interval TN9) constituting of one first interval TN1 and one second interval TN2. Assuming that the predetermined interval is 10 mm, for example, by setting the first interval TN1 equal to a half of the second interval TN2, it is possible to set the first interval TN1 to a value smaller than ⅓ times 10 mm, and to set the second interval TN2 to a value ⅔ times 10 mm.

Furthermore, two or more (e.g., twenty-five) substrates W1 are aligned at the reference pitch (e.g., 10-mm pitch), and two or more (e.g., twenty-five) substrates W2 are aligned at the reference pitch. Furthermore, the twenty-five substrates W2 are arranged offset from the twenty-five substrates W1 by the first interval TN1 (e.g., 3.333 mm) in the alignment direction. As a result, the fifty substrates W including the twenty-five substrates W1 and the twenty-five substrates W2 arranged alternately are aligned at the unequal pitch. The first pitch converting unit 25 then converts the pitch of the fifty substrates W aligned at the unequal pitch, to the narrow pitch (e.g., 3.333-mm pitch). That is, the first pitch conversion is performed by aligning the twenty-five substrates W1 and the twenty-five substrates W2 at the unequal pitch, and the second pitch conversion is performed by converting the unequal pitch to the narrow pitch. By performing the pitch conversion in two stages, it becomes possible to convert the pitch of the twenty-five substrates W1 and the twenty-five substrates W2 that are aligned at the reference pitch easily to the narrow pitch.

In addition, the first pitch conversion for aligning the fifty substrates W aligned at the narrow pitch (e.g., 3.333-mm pitch), having been processed as a batch in the chemical liquid processing bath BT1 or the like, at the unequal pitch is performed. The fifty substrates W, which are aligned at the unequal pitch and in which the twenty-five substrates W1 and the twenty-five substrates W2 are arranged alternately, are decomposed into the twenty-five substrates W1 and the twenty-five substrates W2 both of which are arranged at the reference pitch (e.g., 10-mm pitch). The second pitch conversion is thus performed. By performing the pitch conversion in two stages, fifty substrates W (twenty-five substrates W1 and twenty-five substrates W2) aligned at the narrow pitch can be easily converted to the reference pitch.

### Second Embodiment

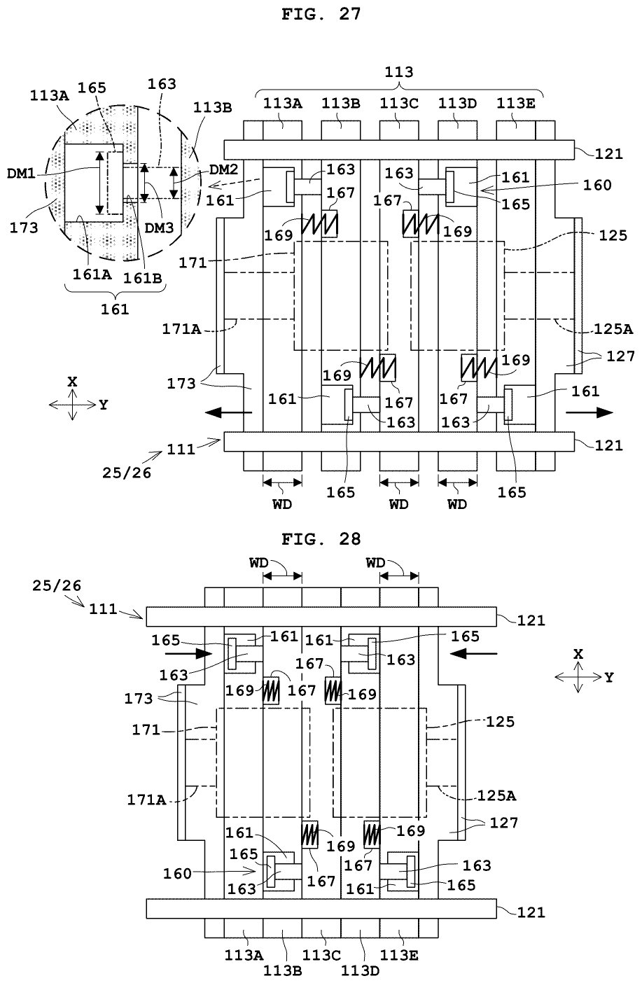

A second embodiment according to the present invention will now be described with reference to drawings. Note that redundant descriptions with those in the first embodiment will be omitted. FIG. 27 is a bottom view mainly illustrating the extending/retracting mechanism 160 included in the pitch converting unit 25 holding the plurality of substrates W that are aligned at the unequal pitch. FIG. 28 is a bottom view mainly illustrating the extending/retracting mechanism 160 included in the pitch converting unit 25 holding a plurality of substrates W that are aligned at the narrow pitch.

In the first embodiment, each of the two pitch converting units 25, 26 includes the link mechanism illustrated in FIGS. 12 and 13, as the extending/retracting mechanism 123. In this regard, in the second embodiment, each of the two pitch converting units 25, 26 may include a housing 161, a protrusion 163, and a stopper 165, illustrated in FIGS. 27 and 28, as the extending/retracting mechanism 160.

FIGS. 27 and 28 will now be referred to. The extending/retracting mechanism 160 includes a plurality of housings 161, a plurality of protrusions 163, and a plurality of stoppers 165. In the configuration in which the pitch converting body 111 includes the twenty-five holding members 113, the extending/retracting mechanism 160 includes twenty-four housings 161, twenty-four protrusions 163, and twenty-four stoppers 165. For every pair of the two adjacent holding members 113, one housing 161, one protrusion 163, and one stopper 165 are provided. FIGS. 27 and 28 will be described focusing on the two adjacent holding members 113A, 113B, as an example. The holding member 113A corresponds to a first holding member according to the present invention. The holding member 113B corresponds to a second holding member according to the present invention.

The housing 161 is provided to the holding member 113A, as an example. As illustrated in an enlarged view inside the circle in FIG. 27, the housing 161 includes a housing body 161A and a joint path 161B. The joint path 161B communicates with the housing body 161A. The joint path 161B opens in a manner facing the holding member 113B.

The protrusion 163 is provided on a side surface of the holding member 113B, the side surface being a surface facing the holding member 113A. In other words, the protrusion 163 protrudes from the holding member 113B toward the holding member 113A. When the plurality of holding members 113 retract in the alignment direction (width direction Y), for example, the protrusion 163 becomes housed inside the housing 161 of the holding member 113A, as illustrated in FIG. 28. Furthermore, with the width WD of the holding members 113 in the width direction Y, the interval between the two holding members 113A and 113B is set to a preset distance. As a result, for example, the fifty holding grooves 117, including the two holding grooves 117 of every holding member 113, become aligned at the narrow pitch (e.g., 3.333-mm pitch).

The stopper 165 is provided at the tip of the protrusion 163. The stopper 165 is housed inside the housing 161. A diameter DM1 (or the width) of the stopper 165 is larger than a diameter DM2 of the protrusion 163. An inner diameter DM3 of the joint path 161B of the housing 161 is smaller than the diameter DM1 of the stopper 165, and larger than the diameter DM2 of the protrusion 163. Therefore, the stopper 165 cannot pass through the joint path 161B, but the protrusion 163 can pass through the joint path 161B. When the plurality of holding members 113 extend in the alignment direction (width direction Y), for example, the stopper 165 prevents the protrusion 163 from coming out of the housing 161, as illustrated in FIG. 27. The interval between the two holding members 113A and 113B is also brought to a preset distance. As a result, the fifty holding grooves 117, for example, are aligned at the unequal pitch.

In the description above, the housing 161 is provided to the holding member 113A, and the protrusion 163 is provided to the holding member 113B. In this regard, the housing 161 may be provided to the holding member 113B, and the protrusion 163 may be provided to the holding member 113A. In addition, as illustrated in FIGS. 27 and 28, two protrusions 163 and two stoppers 165 may be provided to the holding member 113C at the center fixed in the width direction Y.

The extending/retracting mechanism 160 also includes a plurality of holes 167 and a plurality of elastic members 169. In a configuration in which the pitch converting body 111 has twenty-five holding members 113, the extending/retracting mechanism 160 has twenty-four holes 167 and twenty-four elastic members 169. One hole 167 and one elastic member 169 are provided, correspondingly to every pair of the two adjacent holding members 113. The following description is made focusing on the two adjacent holding members 113A, 113B, as an example.

The hole 167 is provided to the holding member 113B, for example. Specifically, the hole 167 is provided on a side surface of the holding member 113B, the side surface being a surface facing the holding member 113A. The hole 167 opens to a space between the two holding members 113A and 113B. The elastic member 169 is, for example, a spring, but may be a sponge. The elastic member 169 is provided between the two holding members 113A and 113B, and one end of the elastic member 169 is housed inside the hole 167. For example, when the plurality of holding members 113 retract in the alignment direction (width direction Y), almost the entirely elastic member 169 becomes housed inside the housing 161, as illustrated in FIG. 28.

The elastic member 169 generates a repulsive force upon receiving an external force. For example, as illustrated in FIGS. 27 and 28, it is preferable for the elastic member 169 to be provided between the two holding members 113A and 113B, in a manner exerting the repulsive force, when the plurality of holding members 113 are extended in the alignment direction (width direction Y) as well as when the plurality of holding members 113 are retracted in the alignment direction (width direction Y).

While the plurality of holding members 113 are in between of being extended in the alignment direction (width direction Y) and retracted in the alignment direction (width direction Y) (in between of being opened and closed), the holding members 113 are free to move from their positions. By providing the plurality of elastic members 169, it is possible to suppress movements of the holding members 113 (including the two holding members 113A, 113B) that are free to move. In this manner, it is possible to suppress shaking of the fifty substrates W held in the fifty holding grooves 117 in the vertical orientation, for example. Thus, it is possible to suppress a contact of two adjacently positioned substrates W, for example.

In the above description, the hole 167 is provided to the holding member 113B. In this regard, the hole 167 may also be provided to the holding member 113A. Furthermore, it is also possible to provide two holes 167 to the holding member 113C at the center.

The moving unit 115 according to the second embodiment includes a second driving unit 171 and a second coupling portion 173, in addition to the base member 119, the two guide rails 121, the extending/retracting mechanism 160, the driving unit 125, and the coupling portion 127 illustrated in FIGS. 27 and 28. In the same manner as the driving unit 125, the second driving unit 171 is also attached to the bottom surface of the base member 119. The second driving unit 171 causes a rod 171A extending in the width direction Y to extend and retract. The second driving unit 171 includes an air cylinder or an electric actuator.

The coupling portion 127 couples the holding member 113E at a first end of the plurality of holding members 113, to a distal end of the rod 125A of the driving unit 125. Similarly, the second coupling portion 173 couples the holding member 113A at a second end of the plurality of holding members 113, to a distal end of the rod 171A of the second driving unit 171. Similarly to the coupling portion 127 illustrated in FIGS. 10 and 11, the second coupling portion 173 is passed through an opening, not illustrated, provided to the base member 119.

The second driving unit 171 causes the rod 171A to extend and to retract in a manner synchronized with the rod 125A being caused to extend and to retract by the driving unit 125. In FIGS. 27 and 28, when the driving unit 125 causes the rod 125A to extend, and the second driving unit 171 causes the rod 171A to extend, the four holding members 113A, 113B, 113D, and 113E are moved away from the holding member 113C at the center. As a result, the plurality of substrates W held by the plurality of holding members 113 become aligned at the unequal pitch. When the driving unit 125 causes the rod 125A to retract and the second driving unit 171 causes the rod 171A to retract, the four holding members 113A, 113B, 113D, and 113E are moved closer to the holding member 113C at the center. As a result, the plurality of substrates W held by the plurality of holding members 113 become aligned at the narrow pitch.

According to the present embodiment, the extending/retracting mechanism 160 can extend/retract the plurality of holding members 113 using the housings 161, the protrusions 163, and the stoppers 165.

A modification of the second embodiment will now be explained. In the second embodiment, the moving unit 115 in each of the pitch converting units 25, 26 includes the extending/retracting mechanism 160 that includes the housings 161, the protrusions 163, and the stoppers 165. In this regard, the moving unit 115 may include the extending/retracting mechanism 123 (e.g., a link mechanism) according to the first embodiment, in addition to the extending/retracting mechanism 160. In such a case, it is possible not to provide the moving unit 115 with the second driving unit 171. In this manner, the one driving unit 125 causes each of the holding members 113 to move along the guide rails 121. In addition, with the stoppers 165 and the width WD of the holding members 113, the interval between the two adjacent holding members 113 are set to the preset distance. In this manner, the positional precision of the two holding members 113 (two holding members 113A, 113E illustrated in FIGS. 12 and 27) at both ends of the extending/retracting mechanism 123 can be further improved.

### Third Embodiment

A third embodiment according to the present invention will now be described with reference to drawings. Note that redundant descriptions with those in the first and the second embodiments will be omitted.

In the first embodiment, the operation of the substrate processing apparatus 1 that processes the fifty substrates W as a batch has been described. In this regard, in the third embodiment, the operation of the substrate processing apparatus 1 that processes seventy-five substrates W as a batch will be described.

The substrate handling mechanism HTR includes, for example, twenty-five or thirteen hands 27 that are arranged at the reference pitch (e.g., 10-mm pitch) in the vertical direction Z. The pair of horizontal holders 37 provided to the orientation converting unit 19 includes, for example, thirty-eight pairs of shelves 37A that are arranged at the reference pitch. The pair of vertical holders 39 provided to the orientation converting unit 19 includes, for example, thirty-eight pairs of holding grooves 39A that are arranged at the reference pitch. The pusher member 55 includes seventy-five or seventy-six vertical holding grooves 67 that are arranged at the unequal pitch.

The chuck 77 of the incoming delivering mechanism 71 includes seventy-five or seventy-six pairs of holding grooves 87, 88 that are arranged at the unequal pitch. The chuck 78 of the intermediating mechanism 73 includes seventy-five or seventy-six pairs of holding grooves 107, 108 that are arranged at the narrow pitch (e.g., 3.333-mm pitch). The chuck 79 of the outgoing delivering mechanism 75 includes seventy-five pairs or seventy-six pairs of holding grooves 95, 96 that are arranged the unequal pitch. Each of the two pitch converting units 25, 26 includes thirty-eight holding members 113. Each of the thirty-eight holding members 113 includes two holding grooves 117 that are spaced apart from each other by the first interval (e.g., 3.333 mm). That is, the thirty-eight holding members 113 have seventy-six holding grooves 117 in total. The thirty-eight holding members 113 may also have seventy-five holding grooves 117 in total.

### <3. Operation of Substrate Processing Apparatus>

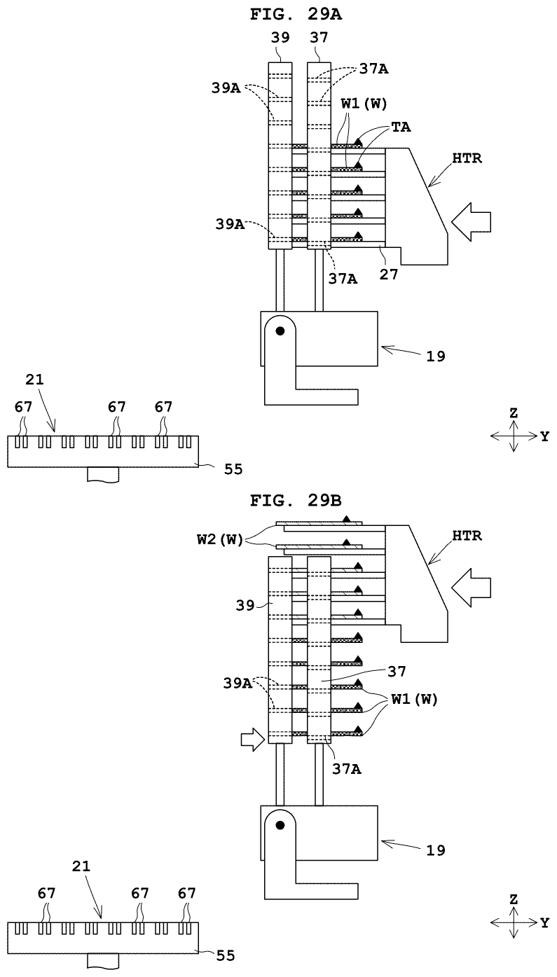

An operation of the substrate processing apparatus 1 will now be described with reference to the flowchart illustrated in FIG. 14. FIGS. 29A to 32B are side views for explaining the operation of the substrate processing apparatus 1. In FIGS. 29A to 32B, for the convenience of illustration, the pair of horizontal holders 37 provided to the orientation converting unit 19 has eight pairs of shelves 37A. The pair of vertical holders 39 in the orientation converting unit 19 has eight pairs of holding grooves 39A. The pusher member 55 has sixteen vertical holding grooves 67.

FIG. 1 will now be referred to. An external transporting robot, not illustrated, transports three carriers C one after another. N (e.g., twenty-five) substrates W1 are housed in the first carrier C. N (e.g., twenty-five) substrates W2 are housed in the second carrier C. N (e.g., twenty-five) substrates W3 are housed in the third carrier C. N is a natural number equal to or more than two. The carrier transporting robot 13 of the stocker 2 then transports the first carrier C from the loading port 9 onto the placing shelf 3.

### [Step S01] Perform Vertical Orientation Conversion of First Substrate Group

FIG. 29A will now be referred to. The substrate handling mechanism HTR transports twenty-five substrates W1 that are aligned at the reference pitch (e.g., 10-mm pitch) in the horizontal orientation, from the first carrier C placed on the placing shelf 3 to the orientation converting unit 19. In other words, the substrate handling mechanism HTR takes out the twenty-five substrates W1 from the first carrier C placed on the placing shelf 3, using the twenty-five hands 27. The substrate handling mechanism HTR then transports the twenty-five substrates W1 having been taken out, to the orientation converting unit 19. The orientation converting unit 19 receives the twenty-five substrates W1 using the twenty-five pairs of shelves 37A, out of the thirty-eight pairs of shelves 37A. The carrier transporting robot 13 transports the empty first carrier C from the placing shelf 3 to the storage shelf 11. The carrier transporting robot 13 then transports the second carrier C from the loading port 9 to the placing shelf 3.

FIG. 29B will now be referred to. The substrate handling mechanism HTR transports P (e.g., thirteen or twelve) substrates W2 that are aligned at the reference pitch in the horizontal orientation, among twenty-five (N) substrates W2, from the second carrier C placed on the placing shelf 3 to the orientation converting unit 19. Note that P is a natural number one, or two or more. In other words, the substrate handling mechanism HTR takes out twenty-five substrates W2 from the second carrier C placed on the placing shelf 3. Then, the substrate handling mechanism HTR transports thirteen substrates W2, which is almost a half of the twenty-five substrates W2 having been taken out, to the orientation converting unit 19.

The orientation converting unit 19 is already holding the twenty-five substrates W1. The orientation converting unit 19 receives thirteen substrates W2 using thirteen pairs of shelves 37A, out of thirty-eight pairs of shelves 37A. As a result, the orientation converting unit 19 comes to hold thirty-eight substrates W1, W2 (the twenty-five substrates W1 and the thirteen substrates W2). These thirty-eight substrates W1, W2 will be referred to as a first substrate group. The housing moving unit 53 (see FIG. 4) of the orientation converting unit 19 then brings the pair of vertical holders 39 closer to the pair of horizontal holders 37.

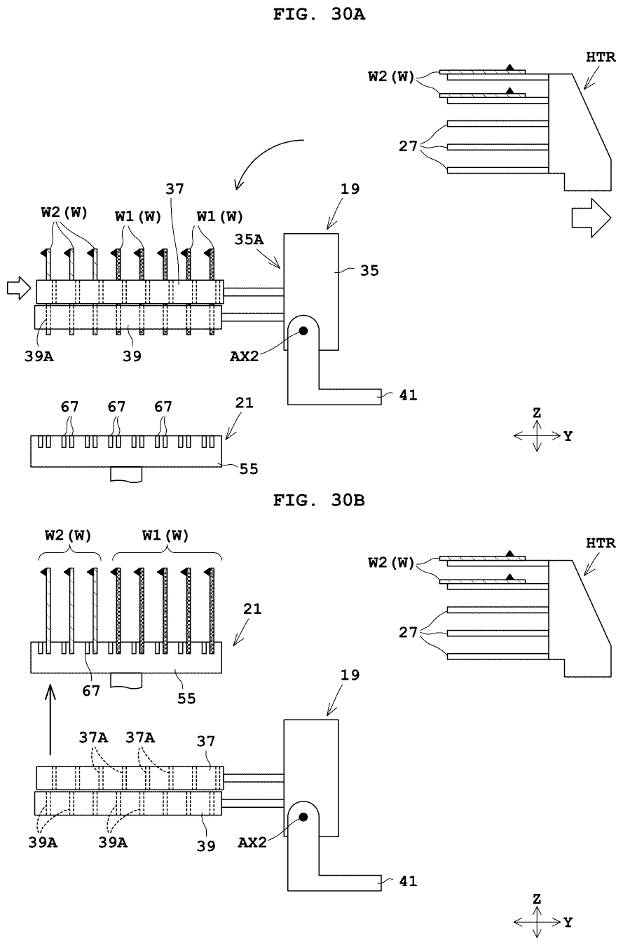

FIG. 30A will now be referred to. The orientation converting unit 19 converts the thirty-eight (two or more) substrates W1, W2 including the twenty-five (N) substrates W1 and the thirteen (P) substrates W2 that are held at the reference pitch, from the horizontal orientation to the vertical orientation. Specifically, the rotation driving unit 41 rotates the elements such as the pair of horizontal holders 37 by 90 degrees about the horizontal axis AX2. As a result, the thirty-eight substrates W1, W2 being held by the pair of horizontal holders 37 and the pair of vertical holders 39 are converted from the horizontal orientation to the vertical orientation. The axial moving unit 51 (see FIG. 4) then moves the pair of horizontal holders 37 in a direction in which the pair of horizontal holders 37 move closer to the support surface 35A so that the thirty-eight pairs of shelves 37A on the pair of horizontal holders 37 move away from the thirty-eight substrates W1, W2 that are in the vertical orientation.

The substrate handling mechanism HTR waits, while holding twelve substrates W2. The carrier transporting robot 13 transports the empty second carrier C from the placing shelf 3 to the storage shelf 11. After the empty second carrier C is transported from the placing shelf 3, the carrier transporting robot 13 transports the third carrier C from the loading port 9 onto the placing shelf 3.

### [Step S02] Cause Pusher Member to Receive First Substrate Group

FIG. 30B will now be referred to. The pusher lift 65 (see FIG. 5) raises the pusher member 55 to a position higher than the pair of horizontal holders 37 and the pair of vertical holders 39. As a result, the pusher member 55 receives the thirty-eight substrates W1, W2 (first substrate group) having the orientation converted to the vertical orientation. The pusher member 55 also holds thirty-eight substrates W1, W2 aligned at the reference pitch.

### [Step S03] Shift First Substrate Group by First Interval

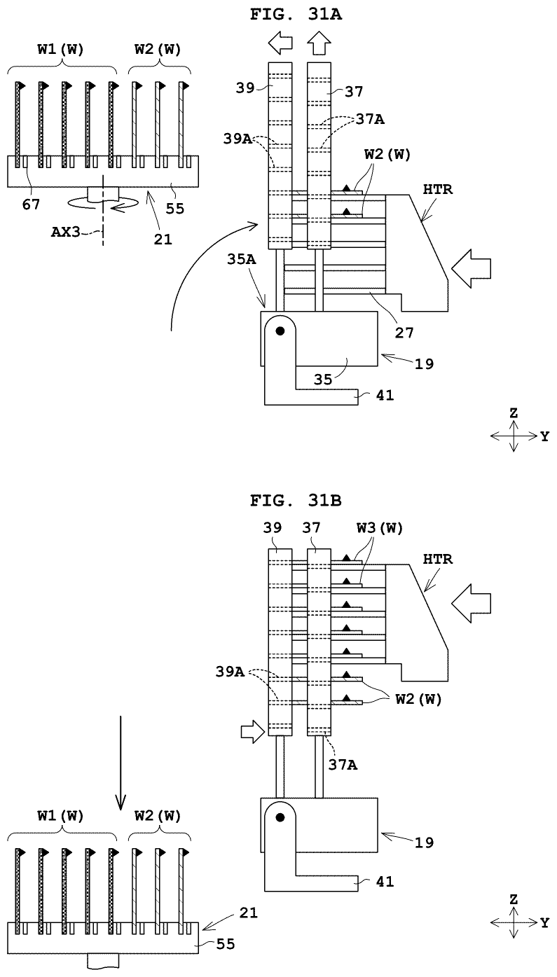

FIG. 31A will now be referred to. The pusher mechanism 21 moves the thirty-eight substrates W1, W2 being held by the pusher member 55 by the first interval TN1 (e.g., 3.333 mm) in the alignment direction of the thirty-eight substrates W1, W2. Specifically, the pusher rotating unit 59 (see FIG. 5) rotates the pusher member 55 by 180 degrees about the vertical axis AX3. As a result, the front surfaces of the thirty-eight substrates W1, W2 come to face rightwards. Furthermore, the thirty-eight substrates W1, W2 being held by the pusher member 55 are moved leftwards by the first interval TN1.

The orientation converting unit 19 also rotates the elements such as the pair of horizontal holders 37 by 90 degrees about the horizontal axis AX2. As a result, the elements such as the pair of horizontal holders 37 are raised. The axial moving unit 51 (see FIG. 4) in the orientation converting unit 19 moves the pair of horizontal holders 37 in the direction moving the pair of horizontal holders 37 away from the support surface 35A. The housing moving unit 53 (see FIG. 4) in the orientation converting unit 19 moves the pair of vertical holders 39 away from the pair of horizontal holders 37.

### [Step S04] Perform Vertical Orientation Conversion of Second Substrate Group

The substrate handling mechanism HTR then transports the remaining twelve (Q) substrates W2 that are aligned at the reference pitch in the horizontal orientation, among the twenty-five (N) substrates W2 from the second carrier C, to the orientation converting unit 19. In other words, the substrate handling mechanism HTR transports twelve (Q) substrates W2 already being held thereby, to the orientation converting unit 19. Among the thirty-eight pairs of shelves 37A of the horizontal holder 37, twelve pairs of shelves 37A receive the twelve substrates W2, respectively. Note that Q is a natural number one, or two or more.

FIG. 31B will now be referred to. The substrate handling mechanism HTR transports twenty-five substrates W3 that are aligned at the reference pitch in the horizontal orientation, from the third carrier C placed on the placing shelf 3 to the orientation converting unit 19. Specifically, the substrate handling mechanism HTR takes out the twenty-five substrates W3 from the third carrier C placed on the placing shelf 3. The substrate handling mechanism HTR then transports the twenty-five substrates W3 having been taken out, to the orientation converting unit 19. The twenty-five pairs of shelves 37A on the horizontal holder 37 receive the twenty-five substrates W3, respectively. As a result, the orientation converting unit 19 comes to hold thirty-seven substrates W2, W3 (the twelve substrates W2 and the twenty-five substrates W3). The thirty-seven substrates W2, W3 will be referred to as a second substrate group.

The housing moving unit 53 (see FIG. 4) brings the pair of vertical holders 39 closer to the pair of horizontal holders 37. The pusher mechanism 21 lowers the pusher member 55 holding the thirty-eight substrates W1, W2. The carrier transporting robot 13 transports the empty third carrier C from the placing shelf 3 to the storage shelf 11.

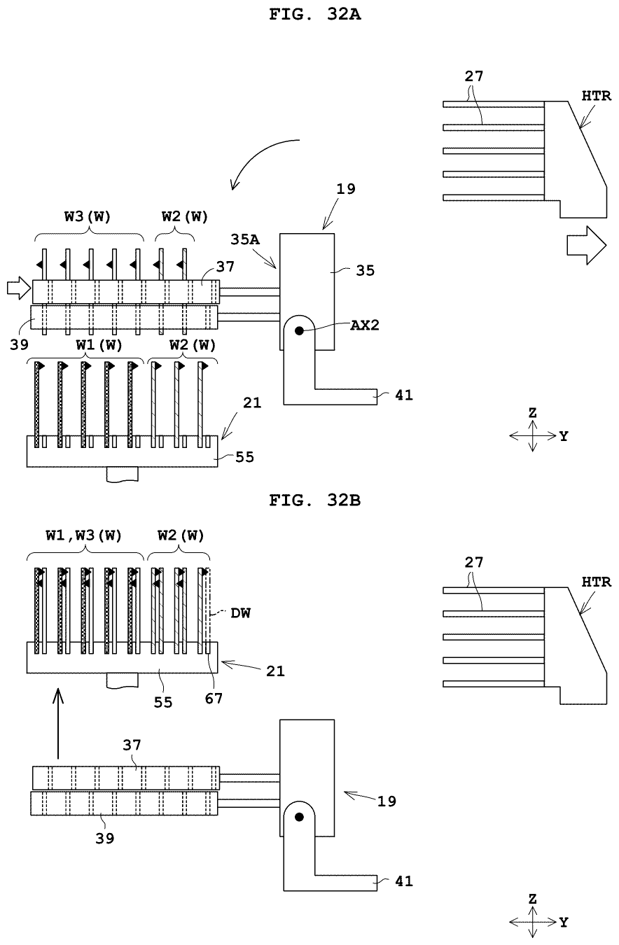

FIG. 32A will now be referred to. The orientation converting unit 19 then converts the thirty-seven (two or more) substrates W2, W3 including the twelve (Q) substrates W2 and the twenty-five (N) substrates W3 that are held at the reference pitch, from the horizontal orientation to the vertical orientation. The axial moving unit 51 (see FIG. 4) then moves the pair of horizontal holders 37 in the direction moving the pair of horizontal holders 37 closer to the support surface 35A.

### [Step S05] Cause Pusher Member to Receive Second Substrate Group

FIG. 32B will now be referred to. The pusher lift 65 (see FIG. 5) then raises the pusher member 55. As a result, the pusher member 55 comes to receive the thirty-seven substrates W2, W3 (second substrate group) having the orientation converted to the vertical orientation. The pusher member 55 holds the seventy-five substrates W (W1, W2, W3) including the thirty-eight substrates W1, W2 and thirty-seven substrates W2, W3 that are arranged alternately, in the vertical orientation. The seventy-five substrates W (processing substrate group) held by the pusher member 55 are aligned at the unequal pitch, as illustrated in FIG. 32B.

As illustrated in FIGS. 32A and 32B, the front surfaces of the thirty-eight substrates W1, W2 face a predetermined direction (rightwards). By contrast, the front surfaces of the thirty-seven substrates W2, W3 face the direction opposite to the predetermined direction (leftwards). That is, the seventy-five substrates W are aligned in a manner what is called face to face. As illustrated in FIG. 32B, a dummy substrate DW may be held in the vertical holding groove 67 not holding the substrate W. That is, the pusher member 55 may hold seventy-five substrates W and one dummy substrate DW (seventy-six substrates in total).

The incoming delivering mechanism 71 of the delivering mechanism 23 then transports seventy-five substrates W that are aligned at the unequal pitch, from the pusher member 55 to the first pitch converting unit 25 (step S06). The first pitch converting unit 25 then converts the pitch of the seventy-five substrates W (processing substrate group) from the unequal pitch to the narrow pitch (step S07). The intermediating mechanism 73 receives the seventy-five substrates W that are aligned at the narrow pitch from the first pitch converting unit 25. The intermediating mechanism 73 transports the seventy-five substrates W to the first delivery position P1 (step S08). Note that the first delivery position P1 is a position where the intermediating mechanism 73 can transfer the seventy-five substrates W to and from the main transporting mechanism WTR.

The main transporting mechanism WTR transports the seventy-five substrates W that are aligned at the narrow pitch to the chemical liquid processing bath BT1, for example. The chemical liquid processing bath BT1 performs the chemical liquid process on the seventy-five substrates W that are aligned at the narrow pitch, as a batch (step S09). Specifically, the main transporting mechanism WTR transports the seventy-five substrates W to the lifter LF1 corresponding to the chemical liquid processing bath BT1, for example. The lifter LF1 then immerses the seventy-five substrates W in the chemical liquid stored in the chemical liquid processing bath BT1, and then immerses the seventy-five substrates W in the pure water stored in the cleaning processing bath BT2. The main transporting mechanism WTR then transports the seventy-five substrates W from the lifter LF1 to the drying unit 143. The drying unit 143 then dries the seventy-five substrates W.

The latter half of the operation of the substrate processing apparatus 1 is performed as in the flowchart illustrated in FIG. 21. The seventy-five substrates W are subjected to processes such as the orientation conversion in the order as illustrated in FIGS. 32B, 32A, 31B, 31A, 30B, 30A, 29B, and 29A. Twenty-five substrates W3 are stored in the third carrier C. The twenty-five substrates W2 are stored in the second carrier C, and the twenty-five substrates W1 are stored in the first carrier C.

According to the present embodiment, the first pitch conversion is performed by aligning N (e.g., twenty-five) substrates W1, W2, and W3 stored at the reference pitch (e.g., 10-mm pitch) in each of the three carriers C, at the unequal pitch, and then the second pitch conversion is performed to convert the unequal pitch to the narrow pitch (e.g., 3.333-mm pitch). By performing the pitch conversion in two stages, it becomes possible to convert the pitch of N substrates W1, W2, W3 that are aligned at the reference pitch in each of the three carriers C, respectively, easily to the narrow pitch.

The present invention is not limited to the embodiments described above, and the following modifications are still possible.

(1) In each of the embodiments described above, when the reference interval TN9 is 10 mm, for example, the first interval TN1 is 3.333 mm, for example, and the second interval TN2 is 6.666 mm, for example. In this case, the first interval TN1 was equal to a half interval of the second interval TN2. In this regard, the first interval TN1 may be smaller than a half interval of the second interval TN2 (larger than 0 (zero) mm). For example, when the reference interval TN9 is 10 mm, for example, the first interval TN1 may be 3 mm, and the second interval TN2 may be 7 mm. The first interval TN1 may be 2.5 mm, and the second interval TN2 may be 7.5 mm. Furthermore, preferably, the second interval TN2 is 2 to 3 times the first interval TN1.

For example, the two holding grooves 117 on each of the holding members 113 may be configured to be spaced apart from each other by a first interval TN1 (e.g., 3 mm) that is smaller than a half interval of the second interval TN2 (e.g., 7 mm), and that is larger than zero (0) mm. In the unequal pitch, the first interval TN1 and the second interval TN2 wider than the first interval TN1 are repeated alternately. Let us assume herein that there is a predetermined interval (reference interval TN9) constituting of one first interval TN1 and one second interval TN2. In a case where the predetermined interval is 10 mm, for example, if the first interval TN1 is smaller than a half of the second interval TN2, the first interval TN1 may be smaller than ⅓ times 10 mm, and the first interval TN1 may have any length such as 3 mm, without any fractional part below the decimal point.

Furthermore, the two holding grooves 117 provided to each of the holding members 113 may be spaced apart from each other by a first interval TN1 (e.g., 3 mm) which is an interval equal to or more than ⅓ times and equal to or less than ½ times the second interval TN2 (e.g., 7 mm).

(2) In each of the embodiments and the modification (1), when the reference interval TN9 is, for example, 10 mm, the first interval TN1 is, for example, 3.333 mm, and the second interval TN2 is, for example, 6.666 mm. In this regard, the first interval TN1 may be larger than the interval ⅓ times the reference interval TN9 (e.g., 3.333 mm) and smaller than an interval ½ times the reference interval TN9 (e.g., 5 mm).

(3) In each of the embodiments and modifications described above, the incoming delivering mechanism 71 is provided on the rear side of the outgoing delivering mechanism 75, but the incoming delivering mechanism 71 may also be provided in front of the outgoing delivering mechanism 75. That is, the positions of the incoming delivering mechanism 71 and the outgoing delivering mechanism 75 may be reversed. In this case, the incoming delivering mechanism 71 transports the plurality of substrates W from the pusher member 55 to the second pitch converting unit 26, and the outgoing delivering mechanism 75 transports the plurality of substrates W from the first pitch converting unit 25 to the pusher member 55.

(4) In each of the embodiments and modifications described above, the intermediating mechanism 73 transports the plurality of substrates W that are aligned at the narrow pitch, from the first pitch converting unit 25 to the main transporting mechanism WTR. In this regard, the intermediating mechanism 73 may transport the plurality of substrates W that are aligned at the narrow pitch, from the main transporting mechanism WTR to the second pitch converting unit 26.

(5) In each of the embodiments and modifications described above, the chuck 77 (the pair of chuck members 77A, 77B) of the incoming delivering mechanism 71 is opened and closed by the opening and closing unit 81. In this respect, it is possible for the chuck 77 not to be opened and closed.

(6) In each of the embodiments and modifications described above, the chuck 79 (the pair of chuck members 79A, 79B) of the outgoing delivering mechanism 75 is opened and closed by the opening and closing unit 89. In this respect, it is possible for the chuck 79 not to be opened and closed.

(7) In each of the embodiments and modifications described above, the substrate processing apparatus 1 processes the fifty substrates W that are aligned face to face, for example, as a batch. In this regard, the substrate processing apparatus 1 may process the fifty substrates W that are aligned face to back, as a batch. The “face to back” herein is an alignment in which the twenty-five substrates W1 of the first substrate group and the twenty-five substrates W2 of the second substrate group face the same direction (e.g., leftwards). In such a case, in step S03 of the flowchart illustrated in FIG. 14, the pusher mechanism 21 does not rotate the pusher member 55 by 180 degrees about the vertical axis AX3, but the pusher horizontally moving unit 61 moves the pusher member 55 by the first interval TN1 in the width direction Y (e.g., 3.333 mm).

(8) In each of the embodiments and modifications described above, the substrate processing apparatus 1 may process one hundred substrates W as a batch. In such a case, the substrate processing apparatus 1 is configured as follows.

The substrate handling mechanism HTR includes, for example, twenty-five or thirteen hands 27 that are arranged at the reference pitch (e.g., 10-mm pitch) in the vertical direction Z. The pair of horizontal holders 37 provided to the orientation converting unit 19 includes, for example, fifty pairs of shelves 37A that are arranged at the reference pitch. The pair of vertical holders 39 provided to the orientation converting unit 19 includes, for example, fifty pairs of holding grooves 39A that are arranged at the reference pitch. The pusher member 55 includes one hundred vertical holding grooves 67 that are arranged at the unequal pitch.

The chuck 77 of the incoming delivering mechanism 71 includes one hundred pairs of holding grooves 87, 88 that are arranged at the unequal pitch. The chuck 78 of the intermediating mechanism 73 includes one hundred pairs of holding grooves 107, 108 that are arranged at the narrow pitch (e.g., 3.333-mm pitch). The chuck 79 of the outgoing delivering mechanism 75 includes a hundred pairs of holding grooves 95, 96 arranged at the unequal pitch. Each of the two pitch converting units 25, 26 includes fifty holding members 113. Each of the fifty holding members 113 includes two holding grooves 117 that are spaced apart from each other by the first interval (e.g., 3.333 mm). That is, the fifty holding members 113 have one hundred holding grooves 117 in total.

Furthermore, the substrate processing apparatus 1 creates a group of one hundred processed substrates as follows. The first substrate group includes the twenty-five substrates W1 corresponding to the first carrier C and the twenty-five substrates W2 corresponding to the second carrier C. The second substrate group includes the twenty-five substrates W3 corresponding to the third carrier C and the twenty-five substrates W4 corresponding to the fourth carrier C. Note that the substrates W4 are not illustrated. The first substrate group and the second substrate group is converted individually, from the horizontal orientation to the vertical orientation by the orientation converting unit 19. In addition, the pusher member 55 holds the one hundred substrates W that are aligned at the unequal pitch. In the one hundred substrates W, fifty substrates W1, W2 and fifty substrates W3, W4 are aligned alternately, and are aligned face to face, for example.

(9) In the embodiments and modifications described above, the transfer block 5 includes the substrate handling mechanism HTR and the orientation converting unit 19, separately. In this regard, the substrate handling mechanism HTR may also be provided with the function of the orientation converting unit 19. In other words, the orientation converting unit 19 may be provided with the function of the substrate handling mechanism HTR. For example, the substrate handling mechanism HTR (or the orientation converting unit 19) takes out thirteen substrates W from the carrier C placed on the placing shelf 3 using thirteen hands 27, and converts the thirteen substrates W thus taken out, from the horizontal orientation to the vertical orientation. Then, the substrate handling mechanism HTR (or the orientation converting unit 19) may arrange the thirteen substrates W in the vertical orientation, in the plurality of vertical holding grooves 67 in the pusher member 55. The orientation converting unit 19 having the function of the substrate handling mechanism HTR corresponds to an orientation converting mechanism according to the present invention.

(10) In each of the embodiments and modifications described above, the delivering mechanism 23 includes the intermediating mechanism 73, but it is also possible for the delivering mechanism 23 not to include the intermediating mechanism 73. In such a case, the main transporting mechanism WTR receives the plurality of substrates W that are aligned at the narrow pitch directly from the first pitch converting unit 25.

(11) In each of the embodiments and modifications described above, the transfer block 5 includes the two pitch converting units 25, 26, but may also include one, or three or more pitch converting units. For example, in a configuration in which the transfer block 5 includes single pitch converting unit 25, it is possible for the transfer block 5 not to include the outgoing delivering mechanism 75, for example. In addition, the single pitch converting unit 25 converts the pitch of the plurality of substrates W to and from the unequal pitch, from and to the narrow pitch.

(12) In each of the embodiments and modifications described above, the incoming delivering mechanism 71 includes the front-back direction moving unit 83 that moves the elements such as the chuck 77 horizontally in the front-back direction X. The outgoing delivering mechanism 75 includes the front-back direction moving unit 91 that horizontally moves the elements such as the chuck 79 in the front-back direction X. Regarding these, it is possible for the incoming delivering mechanism 71 not to include the front-back direction moving unit 83, and for the outgoing delivering mechanism 75 not to include the front-back direction moving unit 91. In such a case, the pusher mechanism 21 may further include a front-back direction moving unit (not illustrated) that horizontally moves the pusher member 55 in the front-back direction X. For example, when the pusher member 55 is horizontally moved in the front-back direction X and the chuck 77 of the incoming delivering mechanism 71 is moved in the width direction Y, the incoming delivering mechanism 71 may receive a plurality of substrates W that are aligned at the unequal pitch in the vertical orientation, from the pusher member 55.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus for processing a plurality of substrates, the substrate processing apparatus comprising:
a pitch converting unit that converts a pitch between the plurality of substrates, between an unequal pitch in which a first interval and a second interval wider than the first interval are repeated alternately, and a narrow pitch in which the first interval is repeated;
a substrate processing unit that processes the plurality of substrates aligned at the narrow pitch, as a batch; and
a main transporting mechanism that transports the plurality of substrates aligned at the narrow pitch to the substrate processing unit, in which
the pitch converting unit includes:
a plurality of holding members that hold the plurality of substrates aligned at the unequal pitch;
a moving unit configured to move the plurality of holding members in an alignment direction of the plurality of substrates so as to switch the plurality of substrates between an unequal pitch arrangement in which the plurality of substrate are arranged at the unequal pitch, and a narrow pitch arrangement in which the plurality of substrates are aligned at the narrow pitch; and
each of the plurality of holding members has two holding grooves that hold two substrates, respectively, among the plurality of substrates, and the two holding grooves are spaced apart from each other by the first interval.

2. The substrate processing apparatus according to claim 1, wherein
the two holding grooves are spaced apart from each other by the first interval that is smaller than a half of the second interval.

3. The substrate processing apparatus according to claim 1, wherein
the two holding grooves are spaced apart from each other by the first interval that is a half of the second interval.

4. The substrate processing apparatus according to claim 1, wherein,
the moving unit includes
a guide rail that supports the plurality of holding members in a manner movable in the alignment direction;
an extending/retracting mechanism that extends and retracts the plurality of holding members in the alignment direction; and
a driving unit that drives the extending/retracting mechanism.

5. The substrate processing apparatus according to claim 4, wherein
the extending/retracting mechanism includes:
a housing that is provided to a first holding member, among the plurality of holding members;
a protrusion that protrudes from a second holding member toward the first holding member positioned adjacently to the second holding member, among the plurality of holding members, and becomes housed in the housing when the plurality of holding members are retracted in the alignment direction; and
a stopper that is provided to a tip of the protrusion, that prevents the protrusion from coming out of the housing when the plurality of holding members are extended in the alignment direction.

6. The substrate processing apparatus according to claim 5, wherein
the extending/retracting mechanism further includes an elastic member provided between the first holding member and the second holding member.

7. The substrate processing apparatus according to claim 1, further comprising:
an orientation converting mechanism that converts the plurality of substrates to and from a horizontal orientation from and to a vertical orientation;
a pusher mechanism that includes a pusher member that holds the plurality of substrates aligned at the unequal pitch in the vertical orientation, and is capable of passing the plurality of substrates to and from the orientation converting mechanism; and
a delivering mechanism that transports the plurality of substrates aligned at the unequal pitch, to and from the pusher member from and to the pitch converting unit.

8. The substrate processing apparatus according to claim 7, further comprising
a control unit, wherein
the control unit is configured to:
cause the orientation converting mechanism to convert two or more first substrates held at a reference pitch in which a reference interval that is a sum of the first interval and the second interval is repeated, from the horizontal orientation to the vertical orientation, as a batch;
cause the pusher member to receive the two or more first substrates having been converted to the vertical orientation, and to hold the two or more first substrates aligned at the reference pitch in the vertical orientation;
cause the pusher mechanism to move the two or more first substrates held by the pusher member by the first interval in an alignment direction of the two or more first substrates;
cause the orientation converting mechanism to convert two or more second substrates held at the reference pitch, from the horizontal orientation to the vertical orientation, as a batch;
cause the pusher member to receive the two or more second substrates having been converted to the vertical orientation;
cause the pusher member to hold the plurality of substrates including the two or more first substrates and the two or more second substrates, the first substrates and the second substrates being arranged alternately and aligned at the unequal pitch;
cause the delivering mechanism to transport the plurality of substrates aligned at the unequal pitch from the pusher member to the pitch converting unit;
cause the pitch converting unit to convert a pitch of the plurality of substrates from the unequal pitch to the narrow pitch;
cause the main transporting mechanism to transport the plurality of substrates aligned at the narrow pitch to the substrate processing unit; and
cause the substrate processing unit to process the plurality of substrates aligned at the narrow pitch as a batch.

9. The substrate processing apparatus according to claim 7, further comprising
a carrier shelf for placing a carrier housing N substrates that are aligned at a reference pitch in which a reference interval that is a sum of the first interval and the second interval is repeated, where N is a natural number equal to or more than two, and
the orientation converting mechanism includes:
an orientation converting unit that converts the two or more first substrates and the two or more second substrates from or to the horizontal orientation to or from the vertical orientation, and
a substrate handling mechanism that transports the N substrates from and to the carrier placed on the carrier shelf, to and from the orientation converting unit.

10. The substrate processing apparatus according to claim 9, further comprising
a control unit, wherein
the control unit is configured to:
cause the substrate handling mechanism to transport N substrates aligned at the reference pitch in the horizontal orientation in a first carrier placed on the carrier shelf, from the first carrier to the orientation converting unit;
cause the substrate handling mechanism to transport P substrates aligned at the reference pitch in the horizontal orientation, the P substrates being substrates among N substrates on a second carrier placed on the carrier shelf, from the second carrier to the orientation converting unit;
cause the orientation converting unit to convert the two or more first substrates including the N substrates from the first carrier and the P substrates held at the reference pitch, from the horizontal orientation to the vertical orientation, as a batch;
cause the pusher member to receive the two or more first substrates having been converted to the vertical orientation, and to hold the two or more first substrates aligned at the reference pitch;
cause the pusher mechanism to move the two or more first substrates held by the pusher member by the first interval in an alignment direction of the two or more first substrates;
cause the substrate handling mechanism to transport Q substrates aligned at the reference pitch in the horizontal orientation to the orientation converting unit, the Q substrates being remainder of the N substrates on the second carrier;
cause the substrate handling mechanism to transport N substrates in the horizontal orientation aligned at the reference pitch on a third carrier placed on the carrier shelf, from the third carrier to the orientation converting unit;
cause the orientation converting unit to convert the two or more second substrates including the Q substrates and the N substrates from the third carrier and held at the reference pitch, from the horizontal orientation to the vertical orientation, as a batch;
cause the pusher member to receive the two or more second substrates having been converted to the vertical orientation;
cause the pusher member to hold the plurality of substrates including the two or more first substrates and the two or more second substrates that are arranged alternately at the unequal pitch;
cause the delivering mechanism to transfer the plurality of substrates that are aligned at the unequal pitch, from the pusher member to the pitch converting unit;
cause the pitch converting unit to convert a pitch of the plurality of substrates from the unequal pitch to the narrow pitch;
cause the main transporting mechanism to transport the plurality of substrates aligned at the narrow pitch to the substrate processing unit; and
cause the substrate processing unit to process the plurality of substrates aligned at the narrow pitch, as a batch.

11. The substrate processing apparatus according to claim 7, further comprising
a control unit, wherein
the control unit is configured to:
cause the main transporting mechanism to transport the plurality of substrates aligned at the narrow pitch in the vertical orientation, the plurality of substrates having been processed as a batch by the substrate processing unit, to a position above the pitch converting unit;
cause the pitch converting unit to hold the plurality of substrates aligned at the narrow pitch in the vertical orientation;
cause the pitch converting unit to convert the pitch of the plurality of substrates from the narrow pitch to the unequal pitch;
cause the delivering mechanism to transport the plurality of substrates aligned at the unequal pitch from the pitch converting unit to the pusher member;
cause the pusher member to hold the plurality of substrates in the vertical orientation, the plurality of substrates being a plurality of substrates that are aligned at the unequal pitch, and in which the two or more first substrates and the two or more second substrates are arranged alternately;
cause the orientation converting mechanism to receive the two or more first substrates aligned at the reference pitch, among the plurality of substrates, from the pusher member, and to convert the two or more first substrates from the vertical orientation to the horizontal orientation; and
cause the orientation converting mechanism to receive the two or more second substrates aligned at the reference pitch, among the plurality of substrates, from the pusher member, and to convert the two or more second substrates from the vertical orientation to the horizontal orientation, wherein
in the reference pitch, a reference interval equal to a sum of the first interval and the second interval is repeated.

12. A substrate processing method for processing a plurality of substrates, the substrate processing method comprising:
a pitch converting step of causing a pitch converting unit to convert a pitch between the plurality of substrates from an unequal pitch in which a first interval and a second interval wider than the first interval are repeated alternately, to a narrow pitch in which the first interval is repeated;
a substrate transporting step of causing a main transporting mechanism to transport the plurality of substrates aligned at the narrow pitch to a substrate processing unit; and
a substrate processing step of causing the substrate processing unit to process the plurality of substrates aligned at the narrow pitch, as a batch, wherein
the pitch converting step includes:
a holding step of causing a plurality of holding members to hold the plurality of substrates aligned at the unequal pitch, while holding two substrates, among the plurality of substrates, at the first interval with two holding grooves that are provided to each of the plurality of holding members and spaced apart from each other by the first interval;
a pitch conversion executing step of causing a moving unit to move the plurality of holding members in an alignment direction of the plurality of substrates so as to switch the plurality of substrates from an unequal pitch arrangement in which the plurality of substrates are aligned at the unequal pitch to a narrow pitch arrangement in which the plurality of substrates are aligned at the narrow pitch.
